(19) United States
(12) Patent Application Publication
(10) Pub. No.: US 2024/0298526 A1
(43) Pub. Date: Sep. 5, 2024

(54) Light Emitting Material for Organic Light Emitting Device, Light Emitting Device and Display Apparatus

(71) Applicant: BOE Technology Group Co., Ltd., Beijing (CN)

(72) Inventors: Yang LIU, Beijing (CN); Xueqin CHEN, Beijing (CN); Kun MA, Beijing (CN)

(21) Appl. No.: 18/023,000

(22) PCT Filed: Apr. 20, 2022
(86) PCT No.: PCT/CN2022/088010

§ 371 Date: Feb. 24, 2023

(51) Int. Cl. H10K 85/60; C09K 11/06; H10K 50/11; H10K 101/30

(52) U.S. Cl. CPC H10K 85/633; C09K 11/06; H10K 85/615; H10K 85/626; H10K 85/636; H10K 85/654; H10K 85/657; H10K 85/6572; H10K 85/6574; H10K 85/6576; C09K 2211/1003; H10K 50/11; H10K 2101/30

(57) ABSTRACT

A light emitting material includes a host material, the host material comprises a first compound having a structural general Formula I.

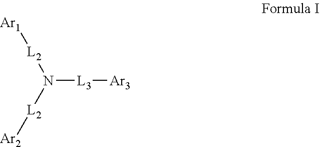

### CROSS-REFERENCE TO RELATED APPLICATION

This application is a national stage application of PCT Application No. PCT/CN2022/088010, which is filed on Apr. 20, 2022 and entitled “Light Emitting Material for Organic Light Emitting Device, Light Emitting Device and Display Apparatus”, the content of which should be regarded as being incorporated herein by reference.

### TECHNICAL FIELD

Embodiments of the present disclosure relate to, but are not limited to, the field of display technology, in particular to a light emitting material for an organic light emitting device, a light emitting device and a display apparatus.

### BACKGROUND

Organic Light Emitting Diode (OLED) is an active light emitting display device, which has the characteristics of self-luminescence, high luminous brightness and efficiency, high resolution, wide color gamut and viewing angle, fast response speed, low energy consumption and flexibility, and has become a hot mainstream display product in the market at present.

Among today's mass-produced OLED devices, red light devices are generally phosphorescent devices. Red host materials are Premix materials, including hole-type host (P-type) materials and electronic-type host (N-type) materials, and P-type host materials and N-type host materials may form an exciplex. The doping material in the red host material (also called Dopant material) is phosphorescent doping material. Excitons are formed on the host material under photoinduced excitation or electroinduced excitation. Excitons are transferred from the host material to the guest material through energy transfer, and then emit light through the radiation transition of the material.

### SUMMARY

The following is a summary of subject matters described herein in detail. The summary is not intended to limit the protection scope of the present application.

An embodiment of the present disclosure provides a light emitting material for an organic light emitting device, including a host material, wherein the host material includes a first compound having the following structural general formula:

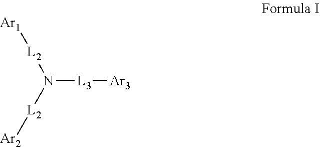

where L₁ to L₃ each independently include any one of a single bond, phenylene, biphenylene, naphthylene, fluorenylene, dimethylfluorenyl, and C1-C10 alkylene; and
Ar₁ to Ar₃ each independently include any one of substituted or unsubstituted phenyl, substituted or unsubstituted biphenyl, substituted or unsubstituted naphthyl, substituted or unsubstituted anthryl, substituted or unsubstituted phenanthrenyl, substituted or unsubstituted carbazole, substituted or unsubstituted dibenzofuryl, substituted or unsubstituted dibenzothienyl, substituted or unsubstituted 9-hydrofluorenyl, substituted or unsubstituted 9,9-dimethylfluorenyl, substituted or unsubstituted 9,9-diphenylfluorenyl, substituted or unsubstituted spirofluorenyl, a substituted or unsubstituted group represented by Formula II, and a substituted or unsubstituted group represented by Formula III; wherein substituted phenyl, substituted biphenyl, substituted naphthyl, substituted anthryl, substituted phenanthrenyl, substituted carbazole, substituted dibenzofuryl, substituted dibenzothienyl, substituted 9-hydrofluorenyl, substituted 9,9-dimethylfluorenyl, substituted 9,9-diphenylfluorenyl, substituted spirofluorenyl, substituted group represented by Formula II, and substituted group represented by Formula III mean being substituted by one or more of the following groups: phenyl, biphenyl, naphthyl, anthryl, phenanthrenyl, carbazolyl, dibenzofuryl, dibenzothienyl, 9-hydrofluorenyl, 9,9-dimethylfluorenyl, 9,9-diphenylfluorenyl, spirofluorenyl, C1 to C10 alkyl, a group represented by Formula II, and a group represented by Formula III;

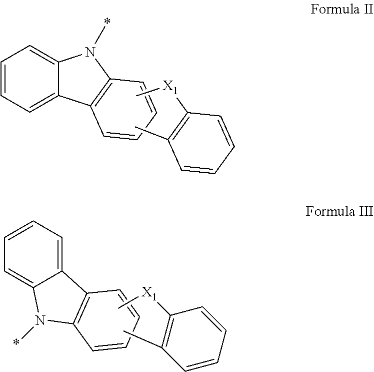

where X₁ includes any one of O, S, NR₁ and CR₂R₃; and
R₁ to R₃ each independently include any one of hydrogen, C1 to C10 alkyl, phenyl, biphenyl, naphthyl, anthryl, phenanthrenyl, carbazole, dibenzofuryl, dibenzothienyl, fluorenyl, dimethylfluorenyl, diphenylfluorenyl, spirofluorenyl.

In an exemplary embodiment, L₁ to L₃ may each independently include any one of a single bond and phenylene; and
Ar₁ to Ar₃ may each independently include any one of phenyl, benzene-substituted phenyl, biphenyl-substituted phenyl, phenanthrene-substituted phenyl, carbazole-substituted phenyl, biphenyl, phenanthrene, carbazole, dimethylfluorenyl, a group represented by Formula II, and a group represented by Formula III, wherein in the group represented by Formula II and the group represented by Formula III, X₁ is O.

In an exemplary embodiment, the first compound may include any one of the following compounds:

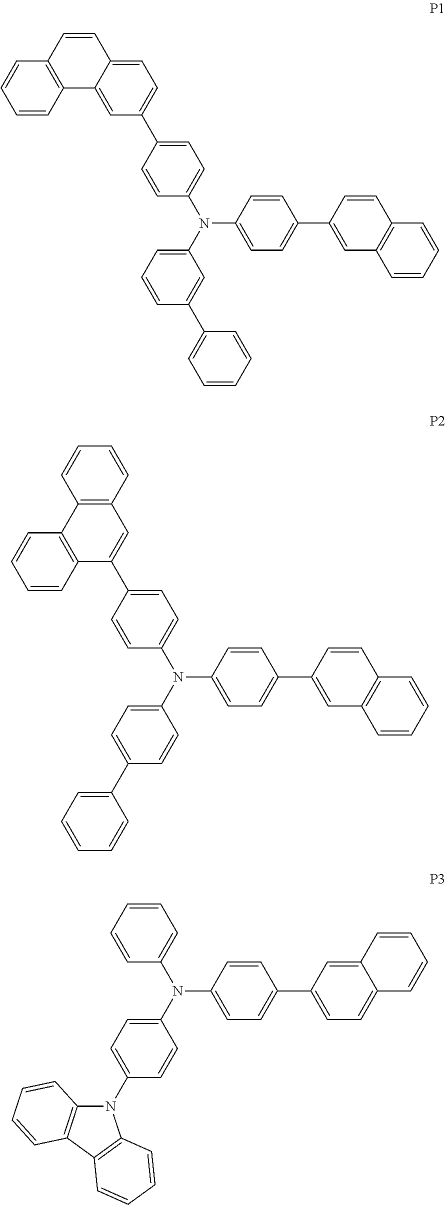 [SMILES: c1ccc(-c2cccc(N(c3ccc(-c4ccc5ccccc5c4)cc3)c3ccc(-c4ccc5ccc6ccccc6c5c4)cc3)c2)cc1 ; c1ccc(-c2ccc(N(c3ccc(-c4ccc5ccccc5c4)cc3)c3ccc(-c4cc5ccccc5c5ccccc45)cc3)cc2)cc1 ; c1ccc(N(c2ccc(-c3ccc4ccccc4c3)cc2)c2ccc(-n3c4ccccc4c4ccccc43)cc2)cc1]

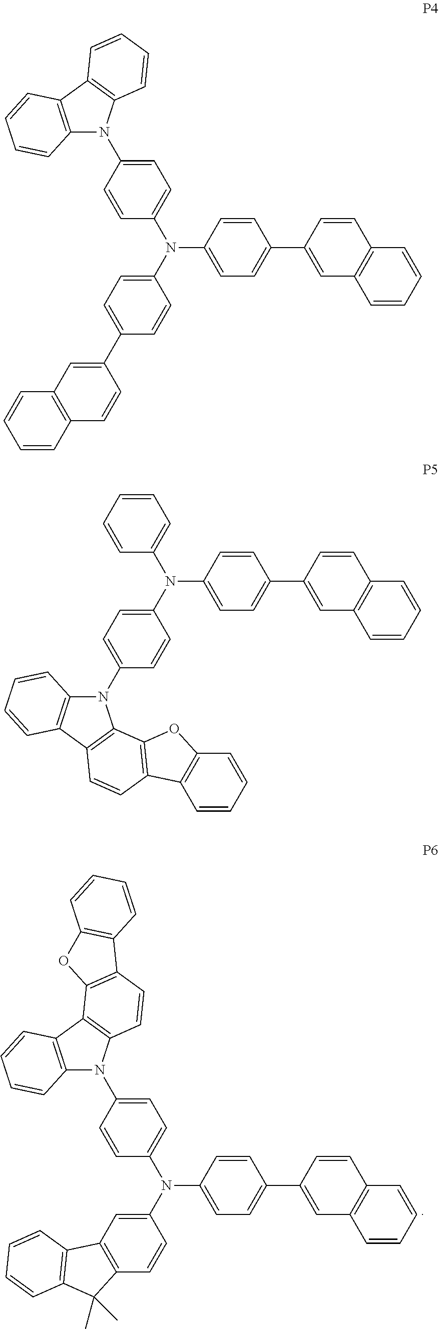 [SMILES: c1ccc2cc(-c3ccc(N(c4ccc(-c5ccc6ccccc6c5)cc4)c4ccc(-n5c6ccccc6c6ccccc65)cc4)cc3)ccc2c1 ; c1ccc(N(c2ccc(-c3ccc4ccccc4c3)cc2)c2ccc(-n3c4ccccc4c4ccc5c6ccccc6oc5c43)cc2)cc1 ; CC1(C)c2ccccc2-c2cc(N(c3ccc(-c4ccc5ccccc5c4)cc3)c3ccc(-n4c5ccccc5c5c6oc7ccccc7c6ccc54)cc3)ccc21]

In an exemplary embodiment, the light emitting material may further include a guest material, and the host material and the guest material may satisfy:

0.1 eV≤T1(H)−T1(D)≤0.5 eV;

2.1 eV≤T1(H)≤2.7 eV; and

2.0 eV≤T1(D)≤2.2 eV;
where T1 (H) is a lowest triplet state energy of the host material, and T1 (D) is a lowest triplet state energy of the guest material.

In an exemplary embodiment, the host material may further include a second compound, and the first compound and the second compound may satisfy:

2.2 eV≤T1(P)≤2.8 eV; and

2.2 eV≤T1(N)≤2.8 eV;
where T1 (P) is a lowest triplet state energy of the first compound, and T1 (N) is a lowest triplet state energy of the second compound.

In an exemplary embodiment, the first compound, the second compound and the guest material may satisfy:

0.1 eV≤|HOMO(P)−HOMO(D)|≤0.4 eV; and

0.1 eV≤|LUMO(N)−LUMO(D)|≤0.5 eV;
where HOMO (P) is a highest occupied molecular orbital energy level of the first compound; LUMO (N) is a lowest unoccupied molecular orbital energy level of the second compound; HOMO (D) is a highest occupied molecular orbital energy level of the guest material; and LUMO (D) is a lowest unoccupied molecular orbital energy level of the guest material.

In an exemplary embodiment, an overlapping integral area of a photoluminescence spectrum of the host material and a metal-to-ligand charge transfer absorption spectrum of the guest material may not be less than 20% of a spectral integral area of the photoluminescence spectrum of the host material.

In an exemplary embodiment, the second compound may have the following general formula:

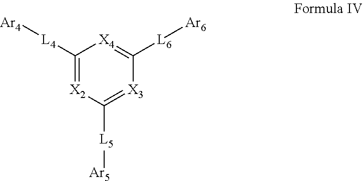

where L₄ to L₆ each independently include any one of a single bond, phenylene, biphenylene, naphthylene, fluorenylene, dimethylfluorenyl, and C1-C10 alkylene;
Ar₄ to Ar₆ each independently include any one of substituted or unsubstituted phenyl, substituted or unsubstituted biphenyl, substituted or unsubstituted naphthyl, substituted or unsubstituted anthryl, substituted or unsubstituted phenanthrenyl, substituted or unsubstituted carbazole, substituted or unsubstituted dibenzofuryl, substituted or unsubstituted dibenzothienyl, substituted or unsubstituted 9-hydrofluorenyl, substituted or unsubstituted 9,9-dimethylfluorenyl, substituted or unsubstituted 9,9-diphenylfluorenyl, substituted or unsubstituted spirofluorenyl, a substituted or unsubstituted group represented by Formula V, and a substituted or unsubstituted group represented by Formula VI, wherein substituted phenyl, substituted biphenyl, substituted naphthyl, substituted anthryl, substituted phenanthrenyl, substituted carbazole, substituted dibenzofuryl, substituted dibenzothienyl, substituted 9-hydrofluorenyl, substituted 9,9-dimethylfluorenyl, substituted 9,9-diphenylfluorenyl, substituted spirofluorenyl, substituted group represented by Formula V, and substituted group represented by Formula VI mean being substituted by one or more of the following groups: phenyl, biphenyl, naphthyl, anthryl, phenanthrenyl, carbazolyl, dibenzofuryl, dibenzothienyl, 9-hydrofluorenyl, 9,9-dimethylfluorenyl, 9,9-diphenylfluorenyl, spirofluorenyl, C1 to C10 alkyl, a group represented by Formula V, and a group represented by Formula VI;

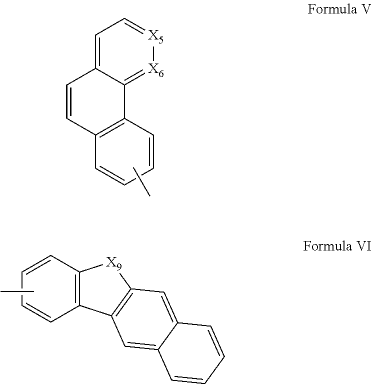

where at least one of X₂ and X₃ is N, and the other is any one of N and —CH; X₄ is N;
X₅ and X₆ each independently include any one of N, C and CH, wherein when both X₅ and X₆ are C, X₅ and X₆ form a ring, which then forms a group represented by Formula V-1 or Formula V-2;

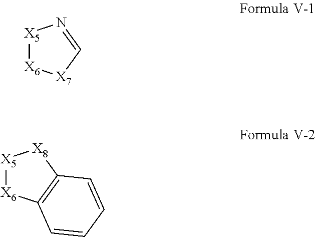

X₇ to X₉ each independently include any one of O, S, NR₄ and CR₅R₆; and
R₄ to R₆ each independently include any one of hydrogen, C1 to C10 alkyl, phenyl, biphenyl, naphthyl, anthryl, phenanthrenyl, carbazole, dibenzofuryl, dibenzothienyl, fluorenyl, dimethylfluorenyl, diphenylfluorenyl, spirofluorenyl.

In an exemplary embodiment, L₄ to L₆ may each independently include any one of a single bond and naphthylene; and
Ar₄ to Ar₆ each independently include any one of phenyl, naphthyl, carbazolyl, carbazole substituted naphthyl, and

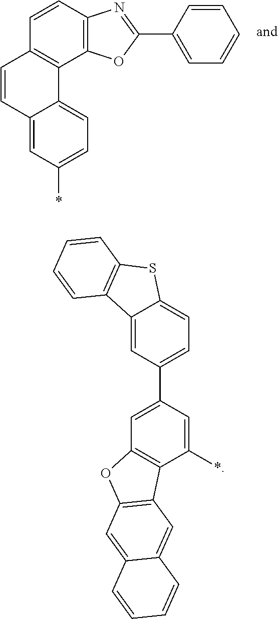

In an exemplary embodiment, the second compound may include any one of the following compounds:

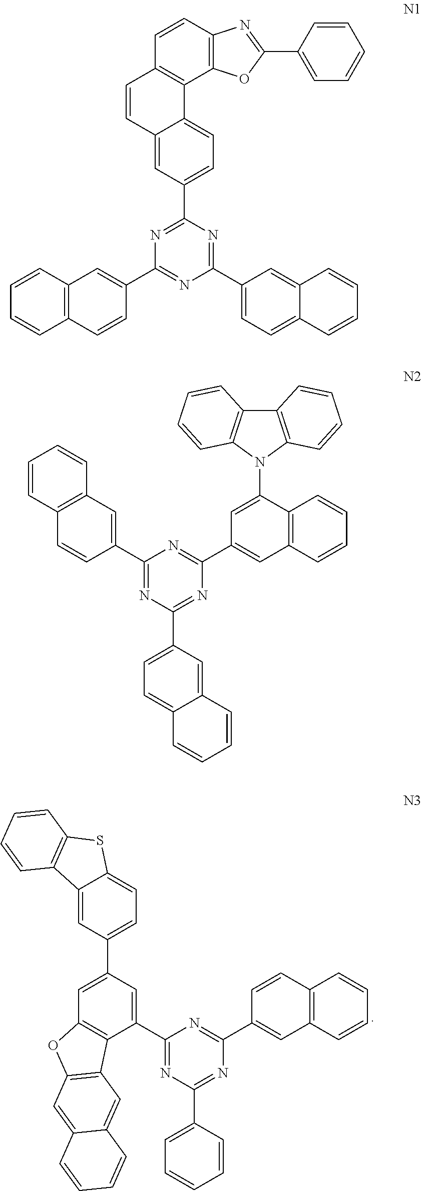 [SMILES: c1ccc(-c2nc3ccc4ccc5cc(-c6nc(-c7ccc8ccccc8c7)nc(-c7ccc8ccccc8c7)n6)ccc5c4c3o2)cc1 ; c1ccc2cc(-c3nc(-c4ccc5ccccc5c4)nc(-c4cc(-n5c6ccccc6c6ccccc65)c5ccccc5c4)n3)ccc2c1 ; c1ccc(-c2nc(-c3ccc4ccccc4c3)nc(-c3cc(-c4ccc5sc6ccccc6c5c4)cc4oc5cc6ccccc6cc5c34)n2)cc1]

In an exemplary embodiment,
the first compound may be P1, and the second compound may be N1; or,
the first compound may be P3, and the second compound may be N2; or,
the first compound may be P5, and the second compound may be N3.

In an exemplary embodiment, the first compound and the second compound may satisfy:

80° C.≤Tg(P)≤140° C.;

80° C.≤Tg(N)≤140° C.; and

|Tg(P)−Tg(N)|≤20° C.;
where Tg (P) is a glass transition temperature of the first compound, and Tg (N) is a glass transition temperature of the second compound.

In an exemplary embodiment, a molar ratio of the first compound to the second compound in the host material may be 3:7 to 7:3.

An embodiment of the present disclosure further provides a light emitting device, including a light emitting layer, wherein a material of the light emitting layer includes the light emitting material for the organic light emitting device as described above.

In an exemplary embodiment, the light emitting device may further include an auxiliary light emitting layer provided on one side of the light emitting layer, and a material of the auxiliary light emitting layer and the first compound may satisfy:

1/100≤hole mobility(F)/hole mobility(P)≤1;
where hole mobility (F) is a hole mobility of the material of the auxiliary light emitting layer, and hole mobility (P) is a hole mobility of the first compound.

In an exemplary embodiment, a material of the auxiliary light emitting layer and the first compound may further satisfy:

0.1 eV≤|HOMO(F)−HOMO(P)|≤0.5 eV; and

|HOMO(F)|>|HOMO(P)|;
where HOMO (F) is a highest occupied molecular orbital (HOMO) energy level of the material of the auxiliary light emitting layer.

In an exemplary embodiment, a material of the auxiliary light emitting layer and the first compound may further satisfy:

0 eV≤T1(F)−T1(P)≤0.4 eV;
where T1 (F) is a lowest triplet state energy of the material of the auxiliary light emitting layer.

In an exemplary embodiment, the material of the auxiliary light emitting layer may have the following general formula:

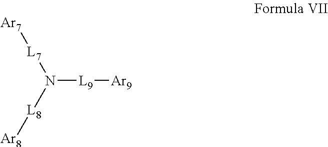

where L₇ to L₉ each independently include any one of a single bond, phenylene, biphenylene, naphthylene, fluorenylene, dimethylfluorenyl, and C1-C10 alkylene;
Ar₇ to Ar₉ each independently include substituted or unsubstituted phenyl, substituted or unsubstituted biphenyl, substituted or unsubstituted naphthyl, substituted or unsubstituted dibenzofuryl, substituted or unsubstituted dibenzothienyl, substituted or unsubstituted 9-hydrofluorenyl, substituted or unsubstituted 9,9-dimethylfluorenyl, substituted or unsubstituted 9,9-diphenylfluorenyl, substituted or unsubstituted spirofluorenyl, substituted or unsubstituted adamantyl, and a substituted or unsubstituted group represented by Formula VIII, wherein substituted phenyl, substituted biphenyl, substituted naphthyl, substituted dibenzofuryl, substituted dibenzothienyl, substituted 9-hydrofluorenyl, substituted 9,9-dimethylfluorenyl, substituted 9,9-diphenylfluorenyl, substituted spirofluorenyl, substituted adamantyl, and substituted group represented by Formula VIII mean being substituted by one or more of the following groups: phenyl, biphenyl, naphthyl, dibenzofuryl, dibenzothienyl, 9-hydrofluorenyl, 9,9-dimethylfluorenyl, 9,9-diphenylfluorenyl, spirofluorenyl, C1 to C10 alkyl, adamantyl, and a group represented by Formula VIII;

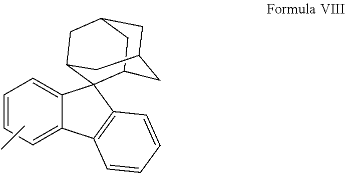

R₇ to R₉ each independently include any one of hydrogen, C1 to C10 alkyl, phenyl, biphenyl, naphthyl, anthryl, phenanthrenyl, carbazole, dibenzofuryl, dibenzothienyl, fluorenyl, dimethylfluorenyl, diphenylfluorenyl, spirofluorenyl.

In an exemplary embodiment, L₇ to L₉ may each independently include any one of a single bond, phenylene, biphenylene, and dimethylfluorenyl; and
Ar₇ to Ar₉ each independently include any one of adamantane-substituted phenyl, adamantane-substituted biphenyl, adamantyl, dibenzofuryl, dimethylfluorenyl, spirofluorenyl, benzene-substituted dimethylfluorenyl, and a group represented by Formula VIII.

In an exemplary embodiment, a material of the auxiliary light emitting layer may include any one of the following compounds:

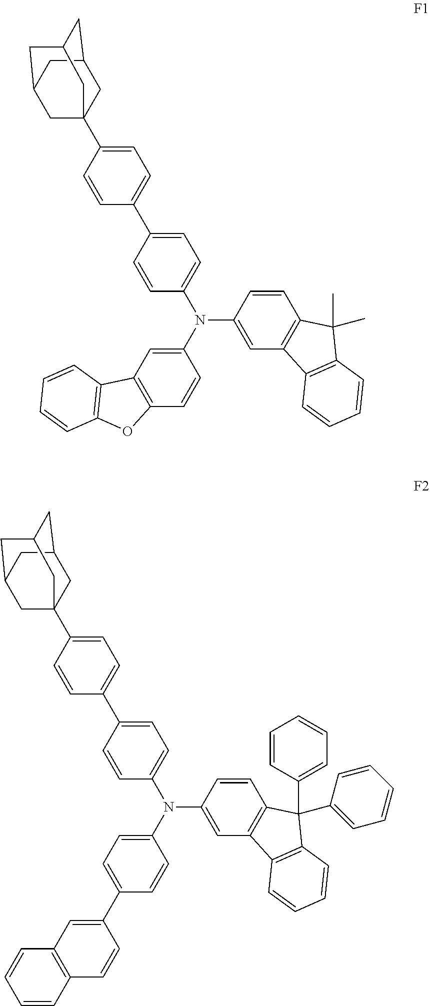 [SMILES: CC1(C)c2ccccc2-c2cc(N(c3ccc(-c4ccc(C56CC7CC(CC(C7)C5)C6)cc4)cc3)c3ccc4oc5ccccc5c4c3)ccc21 ; c1ccc(C2(c3ccccc3)c3ccccc3-c3cc(N(c4ccc(-c5ccc(C67CC8CC(CC(C8)C6)C7)cc5)cc4)c4ccc(-c5ccc6ccccc6c5)cc4)ccc32)cc1]

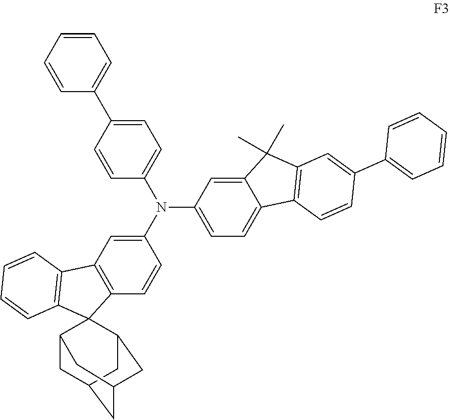 [SMILES: CC1(C)c2cc(-c3ccccc3)ccc2-c2ccc(N(c3ccc(-c4ccccc4)cc3)c3ccc4c(c3)-c3ccccc3C43C4CC5CC(C4)CC3C5)cc21]

In an exemplary embodiment,
the first compound may be P2, and the material of the auxiliary light emitting layer may be F1; or
the first compound may be P4, and the material of the auxiliary light emitting layer may be F2; or
the first compound may be P6, and the material of the auxiliary light emitting layer may be F3.

An embodiment of the present disclosure further provides a display apparatus including the organic light emitting device as described above.

Other aspects may be understood upon reading and understanding the drawings and detailed description.

### BRIEF DESCRIPTION OF DRAWINGS

The accompanying drawings are used for providing understanding of technical solutions of the present disclosure, and form a part of the specification. They are used for explaining the technical solutions of the present disclosure together with the embodiments of the present disclosure, but do not form a limitation on the technical solutions of the present disclosure.

FIG. 1 is a schematic diagram of the formation of a highest occupied molecular orbital energy level trap and a lowest unoccupied molecular orbital energy level trap;

FIG. 2 is a schematic diagram of a device according to an exemplary embodiment of the present disclosure that increases a turn-on voltage of the device by adjusting hole mobility and energy level matching;

FIG. 3 is a schematic structural diagram of a light emitting device according to an exemplary embodiment of the present disclosure;

FIG. 4 is a photoluminescence spectrum (PL) of a host material (RH) and an MLCT3 absorption spectrum of a guest material of a light emitting layer of a device according to an exemplary embodiment and a comparative example of the present disclosure; and

FIG. 5 is curves showing variation of efficiency of a light emitting device according to an exemplary embodiment of the present disclosure and variation of efficiency of a current light emitting device with a current density.

### MEANINGS OF REFERENCE SIGNS IN THE ACCOMPANYING DRAWINGS ARE AS FOLLOWS

10—highest occupied molecular orbital energy level trap; 20—lowest unoccupied molecular orbital energy level trap; 100—anode; 200—hole injection layer; 300—hole transport layer; 400—auxiliary light emitting layer; 500—light emitting layer; 600—hole barrier layer; 700—electron transport layer; 800—electron injection layer; and 900—cathode.

### DETAILED DESCRIPTION

Implementations herein may be implemented in multiple different forms. Those of ordinary skills in the art can readily appreciate a fact that the implementations and contents may be varied into various forms without departing from the spirit and scope of the present disclosure. Therefore, the present disclosure should not be explained as being limited to contents described in following implementations only. The embodiments in the present disclosure and features in the embodiments may be combined randomly with each other without conflict.

In the accompanying drawings, a size of a constituent element, and a thickness of a layer or a region is sometimes exaggerated for clarity. Therefore, any one embodiment of the present disclosure is not necessarily limited to dimensions shown in the drawings, and the shapes and sizes of the components in the accompanying drawings do not reflect actual scales. In addition, the accompanying drawings schematically show an ideal example, and any one embodiment of the present disclosure is not limited to the shapes, values, or the like shown in the accompanying drawings.

In the description of the present disclosure, ordinal numerals such as “first” and “second” are set to avoid confusion of constituents, but not intended for restriction in quantity.

In the specification, a “film” and a “layer” are interchangeable. For example, a “light emitting layer” may be replaced with a “light emitting film” sometimes.

An embodiment of the present disclosure provides a light emitting material for an organic light emitting device, wherein the light emitting material includes a host material including a first compound, the first compound having the following structural general formula:

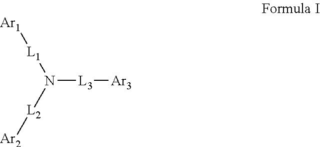

where L₁ to L₃ each independently include any one of a single bond, phenylene, biphenylene, naphthylene, fluorenylene, dimethylfluorenyl, and C1-C10 alkylene;
Ar₁ to Ar₃ each independently include any one of substituted or unsubstituted phenyl, substituted or unsubstituted biphenyl, substituted or unsubstituted naphthyl, substituted or unsubstituted anthryl, substituted or unsubstituted phenanthrenyl, substituted or unsubstituted carbazole, substituted or unsubstituted dibenzofuryl, substituted or unsubstituted dibenzothienyl, substituted or unsubstituted 9-hydrofluorenyl, substituted or unsubstituted 9,9-dimethylfluorenyl, substituted or unsubstituted 9,9-diphenylfluorenyl, substituted or unsubstituted spirofluorenyl, a substituted or unsubstituted group represented by Formula II, and a substituted or unsubstituted group represented by Formula III, wherein substituted phenyl, substituted biphenyl, substituted naphthyl, substituted anthryl, substituted phenanthrenyl, substituted carbazole, substituted dibenzofuryl, substituted dibenzothienyl, substituted 9-hydrofluorenyl, substituted 9,9-dimethylfluorenyl, substituted 9,9-diphenylfluorenyl, substituted spirofluorenyl, substituted group represented by Formula II, and substituted group represented by Formula III mean being substituted by one or more of the following groups: phenyl, biphenyl, naphthyl, anthryl, phenanthrenyl, carbazolyl, dibenzofuryl, dibenzothienyl, 9-hydrofluorenyl, 9,9-dimethylfluorenyl, 9,9-diphenylfluorenyl, spirofluorenyl, C1 to C10 alkyl, a group represented by Formula II, and a group represented by Formula III;

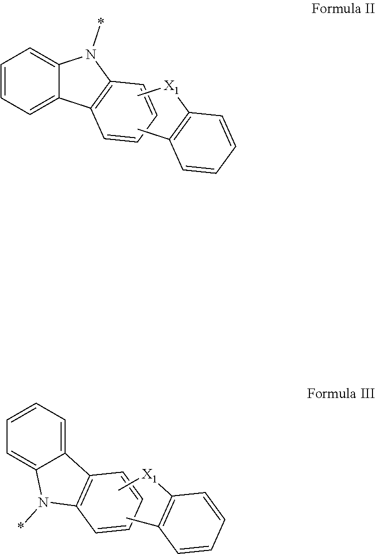

where X₁ includes any one of O, S, NR₁ and CR₂R₃; and
R₁ to R₃ each independently include any one of hydrogen, C1 to C10 alkyl, phenyl, biphenyl, naphthyl, anthryl, phenanthrenyl, carbazole, dibenzofuryl, dibenzothienyl, fluorenyl, dimethylfluorenyl, diphenylfluorenyl, spirofluorenyl.

In an exemplary embodiment, L₁ to L₃ may each independently include any one of a single bond and phenylene; and
Ar₁ to Ar₃ may each independently include any one of phenyl, benzene-substituted phenyl, biphenyl-substituted phenyl, phenanthrene-substituted phenyl, carbazole-substituted phenyl, biphenyl, phenanthrene, carbazole, dimethylfluorenyl, a group represented by Formula II, and a group represented by Formula III, wherein in the group represented by Formula II and the group represented by Formula III, X₁ is O.

In an exemplary embodiment, the first compound may include any one of the following compounds:

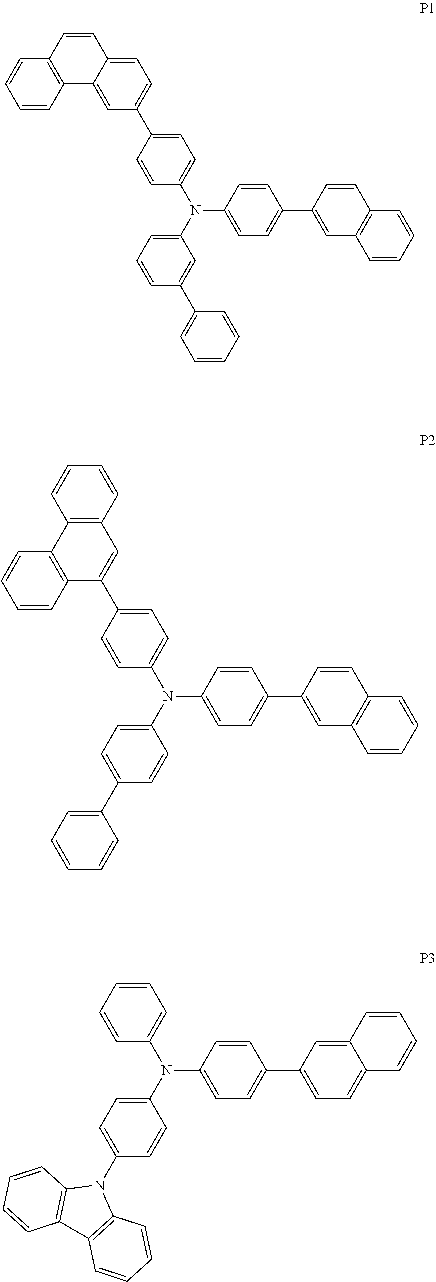 [SMILES: c1ccc(-c2cccc(N(c3ccc(-c4ccc5ccccc5c4)cc3)c3ccc(-c4ccc5ccc6ccccc6c5c4)cc3)c2)cc1 ; c1ccc(-c2ccc(N(c3ccc(-c4ccc5ccccc5c4)cc3)c3ccc(-c4cc5ccccc5c5ccccc45)cc3)cc2)cc1 ; c1ccc(N(c2ccc(-c3ccc4ccccc4c3)cc2)c2ccc(-n3c4ccccc4c4ccccc43)cc2)cc1]

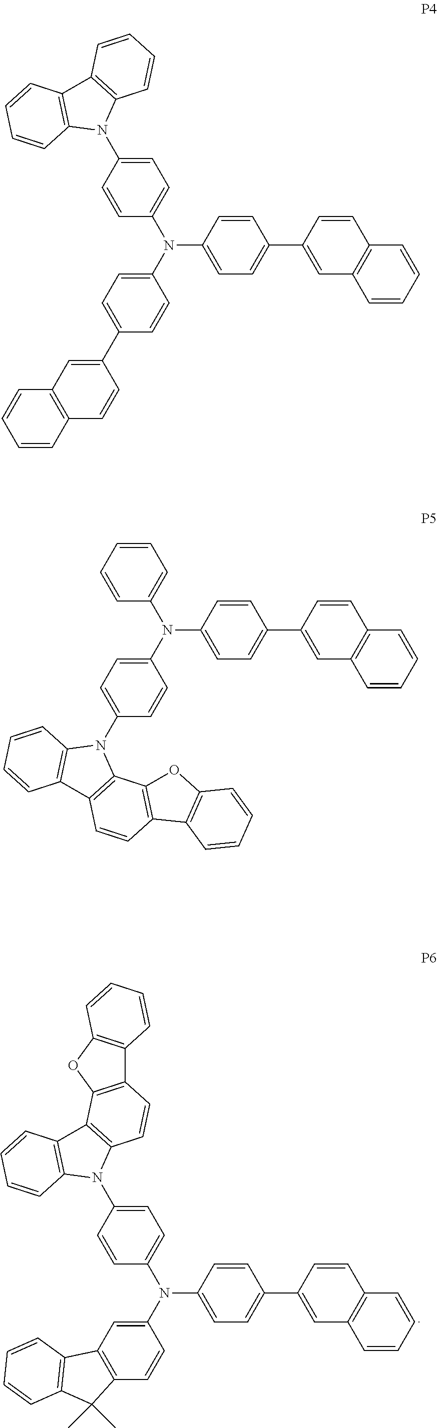 [SMILES: c1ccc2cc(-c3ccc(N(c4ccc(-c5ccc6ccccc6c5)cc4)c4ccc(-n5c6ccccc6c6ccccc65)cc4)cc3)ccc2c1 ; c1ccc(N(c2ccc(-c3ccc4ccccc4c3)cc2)c2ccc(-n3c4ccccc4c4ccc5c6ccccc6oc5c43)cc2)cc1 ; CC1(C)c2ccccc2-c2cc(N(c3ccc(-c4ccc5ccccc5c4)cc3)c3ccc(-n4c5ccccc5c5c6oc7ccccc7c6ccc54)cc3)ccc21]

In an exemplary embodiment, the light emitting material may further include a guest material, and the host material and the guest material may satisfy:

0.1 eV≤T1(H)−T1(D)≤0.5 eV;

2.1 eV≤T1(H)≤2.7 eV; and

2.0 eV≤T1(D)≤2.2 eV;
where T1 (H) is a lowest triplet state energy of the host material, and T1 (D) is a lowest triplet state energy of the guest material.

In the past, it was thought that the higher the T1 of red host material (RH) than that of red guest material (RD), the better, so as to prevent the triplet excitons on the guest material from being transmitted to the host material in reverse. However, we found that when the difference between T1 of red host material (RH) and T1 of red guest material (RD) is too large, the triplet energy loss of exciton transmission from red host material (RH) to red guest material (RD) will be too large, and then the efficiency roll off will be too large at high current density. When the host material and the guest material satisfy 0.1 eV≤T1 (H)−T1 (D)≤0.5 eV, 2.1 eV≤T1 (H)≤2.7 eV, and 2.0 eV≤T1 (D)≤2.2 eV, not only the triplet exciton on the guest material may be prevented from being reversely transmitted to the host material, but also the triplet energy loss when the exciton is transmitted from the red host material (RH) to the red guest material (RD) may be avoided from being too large, and the efficiency roll off under high current density may be reduced.

In an exemplary embodiment, the host material may further include a second compound, and the first compound and the second compound may satisfy:

2.2 eV≤T1(P)≤2.8 eV;

2.2 eV≤T1(N)≤2.8 eV;
where T1 (P) is a lowest triplet state energy of the first compound, and T1 (N) is a lowest triplet state energy of the second compound.

When the first compound and the second compound satisfy 2.2 eV≤T1 (P)≤2.8 eV and 2.2 eV≤T1 (N)≤2.8 eV, 2.1 eV≤T1 (H)≤2.7 eV may be made.

In an exemplary embodiment, the first compound, the second compound and the guest material may satisfy:

0.1 eV≤|HOMO(P)−HOMO(D)|≤0.4 eV; and

0.1 eV≤|LUMO(N)−LUMO(D)|≤0.5 eV;
where HOMO (P) is a highest occupied molecular orbital energy level of the first compound; LUMO (N) is a lowest unoccupied molecular orbital energy level of the second compound; HOMO (D) is a highest occupied molecular orbital energy level of the guest material; and LUMO (D) is a lowest unoccupied molecular orbital energy level of the guest material.

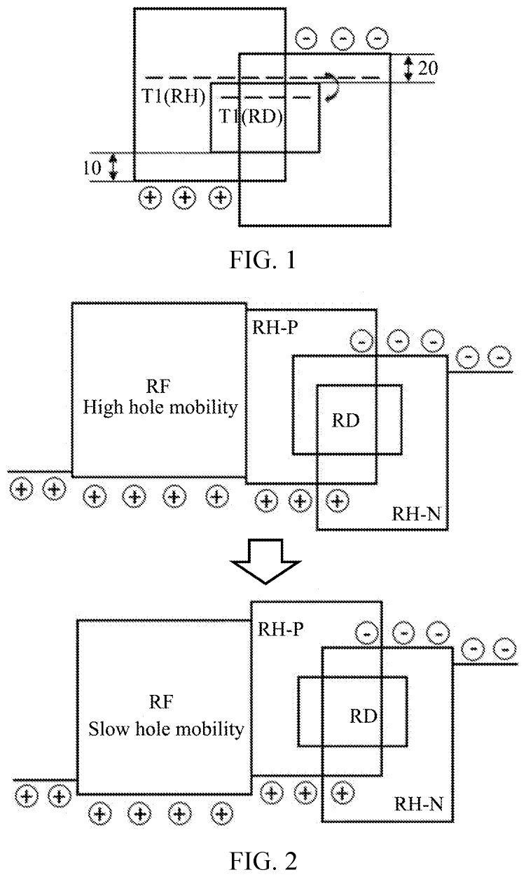

Red guest material (RD) doped in the red host material (RH) will form a Highest Occupied Molecular Orbit trap (HOMO trap) 10 with a P-type host material and a Lowest Unoccupied Molecular Orbit trap (LUMO trap) 20 with an N-type host material. FIG. 1 is a schematic diagram of the formation of a HOMO trap and a LUMO trap. Therefore, the red guest material (RD) will form polarons after capturing charges, and there are triplet excitons transmitted from the red host material (RH) on the red guest material (RD), so it is easy to produce Triplet Exciton-Polaron Annihilation (TPQ) at high current density, which leads to efficiency roll off. When the first compound, the second compound and the guest material satisfy 0.1 eV≤|HOMO(P)−HOMO(D)|≤0.4 eV and 0.1 eV≤|LUMO(N)−LUMO(D)|≤0.5 eV, the trap effect of the guest material on holes and electrons may be reduced, thereby reducing the TPQ under high current density and reducing the efficiency roll off.

In an exemplary embodiment, an overlapping integral area of a photoluminescence spectrum of the host material and a Metal-to-Ligand Charge Transfer (MLCT3) absorption spectrum of the guest material may not be less than 20% of a spectral integral area of the photoluminescence spectrum of the host material. For example, the overlapping integral area of the photoluminescence spectrum of the host material and the MLCT3 absorption spectrum of the guest material may be about 20%, 25%, 30%, 35%, 40%, 45%, 50%, 55% or 60% of the spectral integral area of the photoluminescence spectrum of the host material.

When the overlapping integral area of the photoluminescence spectrum of the host material and the MLCT3 absorption spectrum of the guest material may not be less than 20% of the spectral integral area of the photoluminescence spectrum of the host material, good energy transfer from the host material (e.g., RH) to the guest material (e.g., RD) may be achieved.

In an exemplary embodiment, the guest material may include any one or more of a guest light emitting material of iridium metal complex class, and a guest light emitting material of platinum metal complex class, for example, may include any one or more of tris [1-phenylisoquinoline-C2, N] iridium (III) (Ir (piq)₃), Ir (piq)₂(acac), (MPEP)21r(acac), (PEQ)2Ir(acac), (CzPPiQ) Pt (acac), (CzPPiQ) Pt (dpm) and (DPQ) Pt (acac).

In an exemplary embodiment, a doping ratio of the guest material in the light emitting material may be 1% to 20%, for example, 1%, 2%, 5%, 8%, 10%, 12%, 15%, 18%, and 20%. Within a range of the doping ratio, on the one hand, the host material in the light emitting material may effectively transfer exciton energy to the guest material in the light emitting material to excite the guest material to emit light; on the other hand, the host material in the light emitting material “dilutes” the guest material in the light emitting material, thus effectively improving fluorescence quenching caused by the collision between the molecules of the guest material and the collision between the energies, and improving luminous efficiency and device life. In an exemplary embodiment, the doping ratio refers to a ratio of a mass of the guest material to a mass of the light emitting material, that is, a mass percentage.

In an exemplary embodiment, the second compound may have the following general formula:

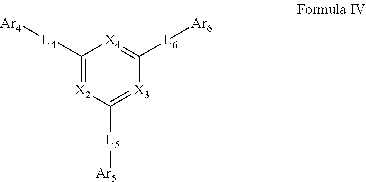

where L₄ to L₆ each independently include any one of a single bond, phenylene, biphenylene, naphthylene, fluorenylene, dimethylfluorenyl, and C1-C10 alkylene;
Ar₄ to Ar₆ each independently include any one of substituted or unsubstituted phenyl, substituted or unsubstituted biphenyl, substituted or unsubstituted naphthyl, substituted or unsubstituted anthryl, substituted or unsubstituted phenanthrenyl, substituted or unsubstituted carbazole, substituted or unsubstituted dibenzofuryl, substituted or unsubstituted dibenzothienyl, substituted or unsubstituted 9-hydrofluorenyl, substituted or unsubstituted 9,9-dimethylfluorenyl, substituted or unsubstituted 9,9-diphenylfluorenyl, substituted or unsubstituted spirofluorenyl, a substituted or unsubstituted group represented by Formula V, and a substituted or unsubstituted group represented by Formula VI, wherein substituted phenyl, substituted biphenyl, substituted naphthyl, substituted anthryl, substituted phenanthrenyl, substituted carbazole, substituted dibenzofuryl, substituted dibenzothienyl, substituted 9-hydrofluorenyl, substituted 9,9-dimethylfluorenyl, substituted 9,9-diphenylfluorenyl, substituted spirofluorenyl, substituted group represented by Formula V, and substituted group represented by Formula VI mean being substituted by one or more of the following groups: phenyl, biphenyl, naphthyl, anthryl, phenanthrenyl, carbazolyl, dibenzofuryl, dibenzothienyl, 9-hydrofluorenyl, 9,9-dimethylfluorenyl, 9,9-diphenylfluorenyl, spirofluorenyl, C1 to C10 alkyl, a group represented by Formula V, and a group represented by Formula VI;

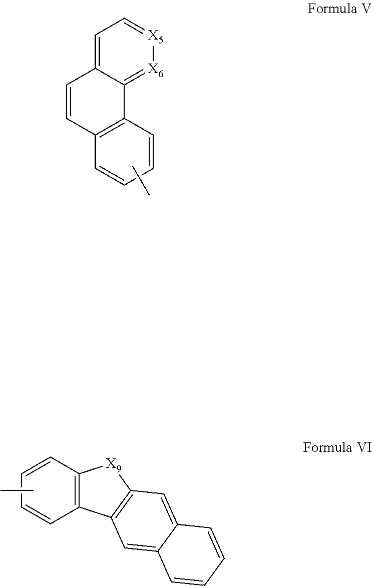

where at least one of X₂ and X₃ is N, and the other is any one of N and —CH; X₄ is N; and
X₅ and X₆ each independently include any one of N, C and CH, wherein when both X₅ and X₆ are C, X₅ and X₆ form a ring, which then forms a group represented by Formula V-1 or Formula V-2;

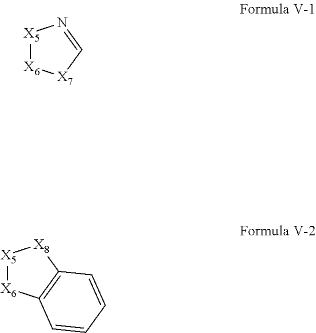

X₇ to X₉ each independently include any one of O, S, NR₄ and CR₅R₆; and
R₄ to R₆ each independently include any one of hydrogen, C1 to C10 alkyl, phenyl, biphenyl, naphthyl, anthryl, phenanthrenyl, carbazole, dibenzofuryl, dibenzothienyl, fluorenyl, dimethylfluorenyl, diphenylfluorenyl, spirofluorenyl.

In an exemplary embodiment, L₄ to L₆ may each independently include any one of a single bond and naphthylene; and
Ar₄ to Ar₆ may each independently include any one of phenyl, naphthyl, carbazolyl, carbazole substituted naphthyl,

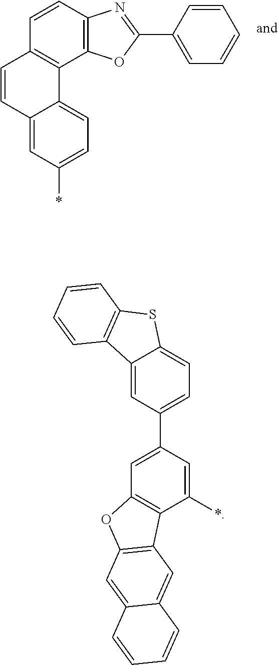

In an exemplary embodiment, the second compound may include any one of the following compounds:

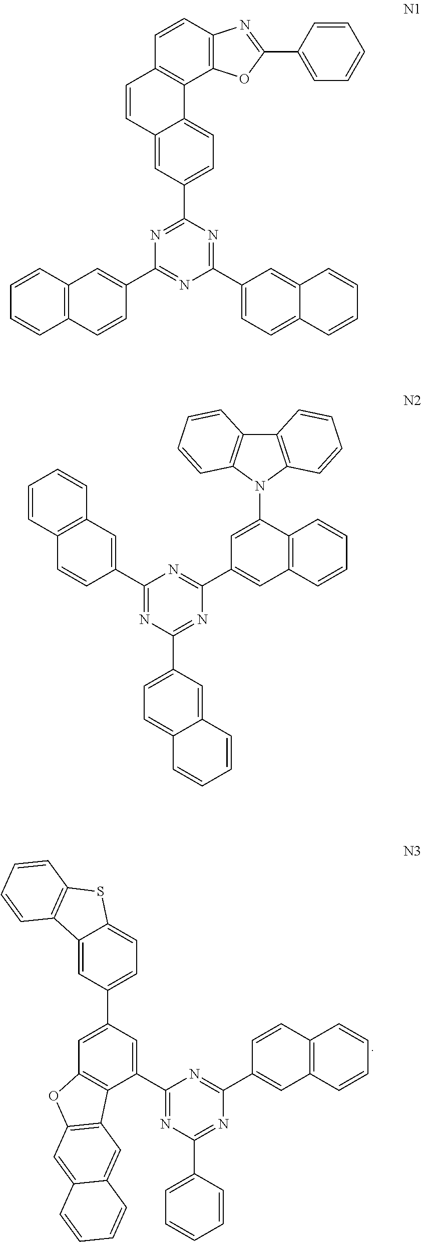 [SMILES: c1ccc(-c2nc3ccc4ccc5cc(-c6nc(-c7ccc8ccccc8c7)nc(-c7ccc8ccccc8c7)n6)ccc5c4c3o2)cc1 ; c1ccc2cc(-c3nc(-c4ccc5ccccc5c4)nc(-c4cc(-n5c6ccccc6c6ccccc65)c5ccccc5c4)n3)ccc2c1 ; c1ccc(-c2nc(-c3ccc4ccccc4c3)nc(-c3cc(-c4ccc5sc6ccccc6c5c4)cc4oc5cc6ccccc6cc5c34)n2)cc1]

In an exemplary embodiment,
the first compound may be P1, and the second compound may be N1; or,
the first compound may be P3, and the second compound may be N2; or,
the first compound may be P5, and the second compound may be N3.
when the above combination of the first compound and the second compound is selected, the first compound and the second compound may simultaneously satisfy: 2.1 eV≤T1 (H)≤2.7 eV; 2.2 eV≤T1 (P)≤2.8 eV; and 2.2 eV≤T1 (N)≤2.8 eV, which is beneficial to reduce the efficiency roll off under high current density.

In an exemplary embodiment, the first compound and the second compound may satisfy:

80° C.≤Tg(P)≤140° C.;

80° C.≤Tg(N)≤140° C.; and

|Tg(P)−Tg(N)|≤20° C.;
where Tg (P) is a glass transition temperature of the first compound, and Tg (N) is a glass transition temperature of the second compound.

When the first compound and the second compound satisfy 80° C.≤Tg(P)≤140° C., 80° C.≤Tg(N)≤140° C., and |Tg(P)−Tg(N)|≤20° C., on the one hand, it may ensure that the first compound and the second compound have good thermal stability, thus ensuring that they are not prone to cracking during long-term evaporation of the first compound and the second compound; on the other hand, when evaporating the first compound and the second compound, they are usually blended together and evaporated using the same heating source. When the first compound and the second compound satisfy 80° C.≤Tg(P)≤140° C., 80° C.≤Tg(N)≤140° C., and Tg(P)−Tg(N)|≤20° C., it may ensure that the ratio of the two materials remains unchanged during the long-term evaporation process.

In an exemplary embodiment, a molar ratio of the first compound to the second compound in the host material may be 3:7 to 7:3. For example, the molar ratio of the first compound to the second compound may be 3:7, 3:8, 3:9, 3:10, 3:20, 3:30, 3:3, 4:3, 5:3, 6:3, and 7:3.

In an exemplary embodiment, the first compound may serve as a P-type host material among the host materials, and the second compound may serve as an N-type host material among the host materials.

An embodiment of the present disclosure further provides a light emitting device, including a light emitting layer, wherein a material of the light emitting layer includes the light emitting material for the organic light emitting device as described above.

When the light emitting layer of the light emitting device is prepared by using the light emitting material for the organic light emitting device provided by the embodiment of the present disclosure, the efficiency roll off of the light emitting device under a large current density may be obviously reduced.

In an exemplary embodiment, the light emitting device may further include an auxiliary light emitting layer provided on one side of the light emitting layer, and a material of the auxiliary light emitting layer and the first compound may satisfy:

1/100≤hole mobility(F)/hole mobility(P)≤1;
where hole mobility (F) is a hole mobility of the material of the auxiliary light emitting layer, and hole mobility (P) is a hole mobility of the first compound.

At present, the hole injection layer of the device is generally P-type doped structure, which will reduce the transverse resistance of the hole injection layer and lead to the transverse drift of the hole. Because the energy of red light is smaller than that of green light and blue light, and the turn-on voltage of red light device is smaller than that of green light device and blue light device, the laterally drifting charge may easily lead to the lighting of red pixels that are not expected to be lit, resulting in crosstalk.

In current mass-produced OLED devices, a thickness of red auxiliary light emitting layer is about 2 to 8 times that of green auxiliary light emitting layer and blue auxiliary light emitting layer. Therefore, the mobility of the red auxiliary light emitting layer is closely related to the turn-on voltage of the red light device. The light emitting device according to the exemplary embodiment of the present disclosure causes the material of the auxiliary light emitting layer and the first compound to satisfy 1/100≤hole mobility (F)/hole mobility (P)≤1, which is conducive to reducing the injection of holes into the light emitting layer, delaying the recombination of holes and electrons, and improving the turn-on voltage of the device.

In an exemplary embodiment, a material of the auxiliary light emitting layer and the first compound may further satisfy:

0.1 eV≤|HOMO(F)−HOMO(P)|≤0.5 eV; and

|HOMO(F)|>|HOMO(P)|;
where HOMO (F) is a highest occupied molecular orbital (HOMO) energy level of the material of the auxiliary light emitting layer.

The highest occupied molecular orbital energy gap (HOMO gap) of the material of the red auxiliary light emitting layer and the red P-type host material also affects the hole injection from the red auxiliary light emitting layer material to the light emitting layer. When the material of the auxiliary light emitting layer and the first compound satisfy 0.1 eV≤|HOMO(F)−HOMO(P)|≤0.5 eV, and |HOMO(F)|>|HOMO(P)|, it is conducive to reducing the injection of holes into the light emitting layer, delaying the recombination of holes and electrons, and improving the turn-on voltage of the device.

FIG. 2 is a schematic diagram of a device according to an exemplary embodiment of the present disclosure that increases a turn-on voltage of the device by adjusting hole mobility and energy level matching. The upper figure shows the present red light device, and the lower figure shows the red light device according to an exemplary embodiment of the present disclosure, where RF represents a material of an auxiliary light emitting layer, RH—P represents a P-type host material of the light emitting layer, RH—N represents an N-type host material of the light emitting layer, and RD represents a guest material of the light emitting layer.

In an exemplary embodiment, a material of the auxiliary light emitting layer and the first compound may further satisfy:

0 eV≤T1(F)−T1(P)≤0.4 eV;
where T1 (F) is a lowest triplet state energy of the material of the auxiliary light emitting layer.

When the material of the auxiliary light emitting layer and the first compound satisfy 0 eV≤T1 (F)−T1 (P)≤0.4 eV, triplet excitons may be prevented from leaking out to the auxiliary light emitting layer, and the role of the auxiliary light emitting layer in blocking triplet excitons may be fully exerted.

In an exemplary embodiment, the material of the auxiliary light emitting layer may have the following general formula:

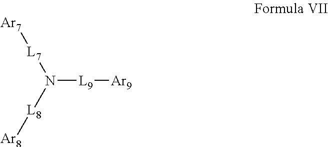

where L₇ to L₉ each independently include any one of a single bond, phenylene, biphenylene, naphthylene, fluorenylene, dimethylfluorenyl, and C1-C10 alkylene;
Ar₇ to Ar₉ each independently include substituted or unsubstituted phenyl, substituted or unsubstituted biphenyl, substituted or unsubstituted naphthyl, substituted or unsubstituted dibenzofuryl, substituted or unsubstituted dibenzothienyl, substituted or unsubstituted 9-hydrofluorenyl, substituted or unsubstituted 9,9-dimethylfluorenyl, substituted or unsubstituted 9,9-diphenylfluorenyl, substituted or unsubstituted spirofluorenyl, substituted or unsubstituted adamantyl, and a substituted or unsubstituted group represented by Formula VIII, wherein substituted phenyl, substituted biphenyl, substituted naphthyl, substituted dibenzofuryl, substituted dibenzothienyl, substituted 9-hydrofluorenyl, substituted 9,9-dimethylfluorenyl, substituted 9,9-diphenylfluorenyl, substituted spirofluorenyl, substituted adamantyl, and substituted group represented by Formula VIII mean being substituted by one or more of the following groups: phenyl, biphenyl, naphthyl, dibenzofuryl, dibenzothienyl, 9-hydrofluorenyl, 9,9-dimethylfluorenyl, 9,9-diphenylfluorenyl, spirofluorenyl, C1 to C10 alkyl, adamantyl, and a group represented by Formula VIII; and

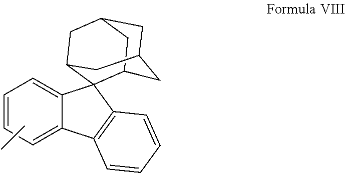

R₇ to R₉ each independently include any one of hydrogen, C1 to C10 alkyl, phenyl, biphenyl, naphthyl, anthryl, phenanthrenyl, carbazole, dibenzofuryl, dibenzothienyl, fluorenyl, dimethylfluorenyl, diphenylfluorenyl, spirofluorenyl.

In an exemplary embodiment, L₇ and L₉ may each be independently selected from any one of a single bond, phenylene, biphenylene, and dimethylfluorenyl; and
Ar₇ to Ar₉ may each independently include any one of adamantane-substituted phenyl, adamantane-substituted biphenyl, adamantyl, dibenzofuryl, dimethylfluorenyl, spirofluorenyl, benzene-substituted dimethylfluorenyl, and a group represented by Formula VIII.

In an exemplary embodiment, a material of the auxiliary light emitting layer may include any one of the following compounds:

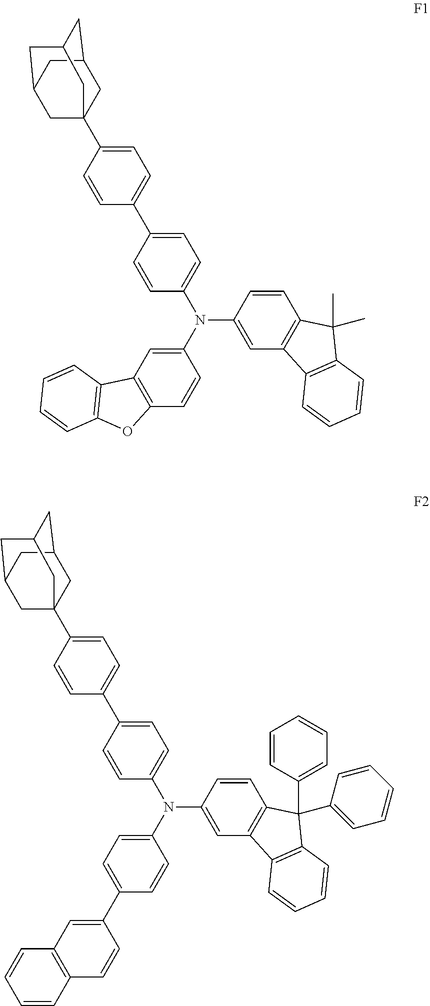 [SMILES: CC1(C)c2ccccc2-c2cc(N(c3ccc(-c4ccc(C56CC7CC(CC(C7)C5)C6)cc4)cc3)c3ccc4oc5ccccc5c4c3)ccc21 ; c1ccc(C2(c3ccccc3)c3ccccc3-c3cc(N(c4ccc(-c5ccc(C67CC8CC(CC(C8)C6)C7)cc5)cc4)c4ccc(-c5ccc6ccccc6c5)cc4)ccc32)cc1]

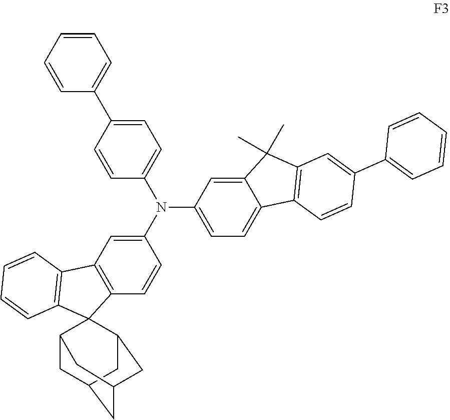 [SMILES: CC1(C)c2cc(-c3ccccc3)ccc2-c2ccc(N(c3ccc(-c4ccccc4)cc3)c3ccc4c(c3)-c3ccccc3C43C4CC5CC(C4)CC3C5)cc21]

In an exemplary embodiment,
the first compound may be P2, and the material of the auxiliary light emitting layer may be F1; or
the first compound may be P4, and the material of the auxiliary light emitting layer may be F2; or
the first compound may be P6, and the material of the auxiliary light emitting layer may be F3.

When the above combination of the first compound and the material of the auxiliary light emitting layer is selected, the material of the auxiliary light emitting layer and the first compound may simultaneously satisfy. 1/100≤hole mobility (F)/hole mobility (P)≤1, 0.1 eV≤|HOMO(F)−HOMO(P)|≤0.5 eV, and |HOMO(F)|>|HOMO(P)|, so that the injection of holes into the light emitting layer may be reduced, the recombination of holes and electrons may be delayed, and the turn-on voltage of the device may be improved.

In an exemplary embodiment, the light emitting device may include an anode, a cathode, and an organic light emitting layer provided between the anode and the cathode, wherein the organic light emitting layer includes an emitting layer (EML).

In an exemplary embodiment, the organic emitting layer may further include any one or more layers of: a Hole Injection Layer (HIL), a Hole Transport Layer (HTL), an Electron Block Layer (EBL), an auxiliary light emitting layer, an Emitting Layer (EML), a Hole Block Layer (HBL), an Electron Transport Layer (ETL), and an Electron Injection Layer (EIL). In an exemplary embodiment, one or more layers of the hole injection layer, the hole transport layer, the electron block layer, the hole block layer, the electron transport layer, and the electron injection layer of all sub-pixels may be a common layer communicated together. Emitting layers of adjacent sub-pixels may be overlapped slightly, or may be mutually isolated.

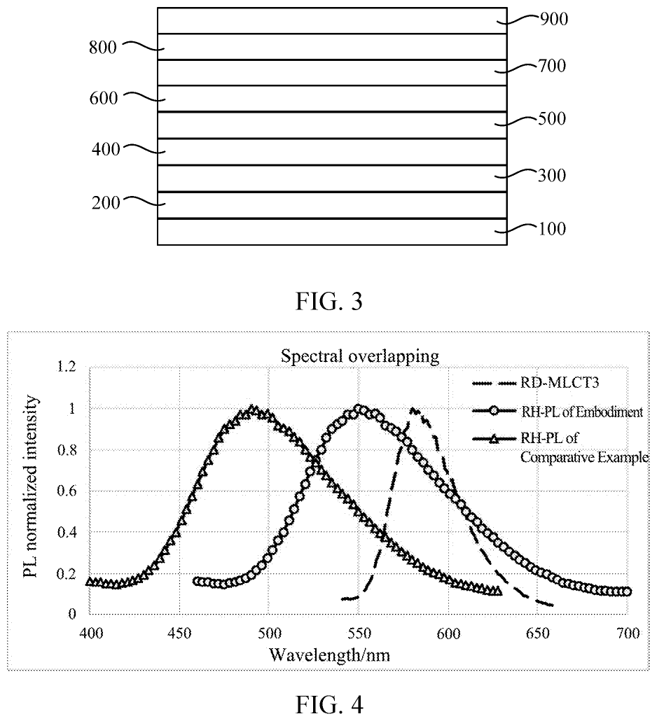

FIG. 3 is a schematic structural diagram of a light emitting device according to an exemplary embodiment of the present disclosure. As shown in FIG. 3, The electroluminescent device may include: an anode 100, a hole injection layer 200, a hole transport layer 300, an auxiliary light emitting layer 400, an emitting layer 500, a hole block layer 600, an electron transport layer 700, an electron injection layer 800 and a cathode 900. The hole injection layer 200 is provided on a surface on one side of the anode 100, the hole transport layer 300 is provided on a surface of the hole injection layer 200 on a side away from the anode 100, the auxiliary light emitting layer 400 is provided on a surface of the hole transport layer 300 on a side away from the anode 100, the emitting layer 500 is provided on a surface of the auxiliary light emitting layer 400 on a side away from the anode 100, the hole block layer 600 is provided on a surface of the emitting layer 500 on a side away from the anode 100, the electron transport layer 700 is provided on a surface of the hole barrier layer 600 on a side away from the anode 100, the electron injection layer 800 is provided on a surface of the electron transport layer 700 on a side away from the anode 100, and the cathode 900 is provided on a surface of the electron injection layer 800 on a side away from the anode 100.

In an exemplary embodiment, the organic emitting layer may be prepared by the following preparation method. Firstly, a hole injection layer, a hole transport layer, and an electron block layer are formed sequentially using an evaporation process of an Open Mask (OPM) or an ink-jet printing process, and a common layer of the hole injection layer, the hole transport layer, and the electron block layer is formed on a display substrate. Then, a red emitting layer, a green emitting layer, and a blue emitting layer are respectively formed in corresponding sub-pixels using an evaporation process of a Fine Metal Mask (FMM) or an ink-jet printing process. Emitting layers of adjacent sub-pixels may be overlapped slightly (e.g. an overlapping portion accounts for less than 10% of an area of a respective pattern of an emitting layer) or may be isolated. Subsequently, a hole block layer, an electron transport layer, and an electron injection layer are formed in sequence using an evaporation process of an open mask or an ink-jet printing process. A common layer of the hole blocking layer, the electron transport layer, and the electron injection layer is formed on the display substrate.

In an exemplary embodiment, the organic light emitting layer may further include a microcavity adjustment layer, so that a thickness of the organic light emitting layer between a cathode and an anode satisfies a design of a length of a microcavity. In an exemplary embodiment, a hole transport layer, an electron block layer, a hole block layer, or an electron transport layer may be used as a microcavity adjustment layer, which is not limited in the present disclosure.

In an exemplary embodiment, the host material and the guest material of the emitting layer may be co-evaporated through a multi-source evaporation process, so that the host material and the guest material are uniformly dispersed in the emitting layer. A doping ratio may be adjusted by controlling an evaporation rate of the guest material or by controlling an evaporation rate ratio of the host material to the guest material during an evaporation process. In an exemplary embodiment, a thickness of the emitting layer may be about 10 nm to 50 nm.

In an exemplary embodiment, the hole injection layer may be made of an inorganic oxide, such as molybdenum oxide, titanium oxide, vanadium oxide, rhenium oxide, ruthenium oxide, chromium oxide, zirconium oxide, hafnium oxide, tantalum oxide, silver oxide, tungsten oxide or manganese oxide, or may be made of a p-type dopant of a strong electron absorption system and a dopant of a hole transport material, such as a dopant of 4,4′-cyclohexylbis[N,N-bis(4-methylphenyl)aniline] (TAPC) and 2,3,6,7,10,11-hexacyano-1,4,5,8,9,12-hexaazatriphenylene (HAT-CN). In an exemplary embodiment, a thickness of the hole injection layer may be about 5 nm to 20 nm.

In an exemplary embodiment, the hole transport layer may be made of a material with a relatively high hole mobility, such as an aromatic amine compound, and its substituent group may be carbazole, methylfluorene, spirofluorene, dibenzothiophene, or furan, such as TAPC, etc. In an exemplary embodiment, a thickness of the hole transport layer may be about 40 nm to 150 nm.

In an exemplary embodiment, a hole block layer and an electron transport layer may be made of aromatic heterocyclic compounds, such as benzimidazole derivatives, imidazopyridine derivatives, benzimidazophenanthridine derivatives, and other imidazole derivatives; pyrimidine derivatives, triazine derivatives, and other azine derivatives; quinoline derivatives, isoquinoline derivatives, phenanthroline derivatives, and other compounds containing a nitrogen-containing six-membered ring structure (also including compounds having a phosphine oxide-based substituent on a heterocyclic ring). For another example, the material of the hole block layer m and the material of the electron transport layer may include any one or more of 2-(4-biphenyl)-5-(4-tert-butylphenyl)-1,3,4-oxadiazole (PBD), 1,3-bis[5-(p-tert-butylphenyl)-1,3,4-oxadiazol-2-yl]benzene (OXD-7), 3-(biphenyl-4-yl)-5-(4-tert-butylphenyl)-4-phenyl-4H-1,2,4-triazole (TAZ), 3-(4-tert-butylphenyl)-4-(4-ethyl Phenyl)-5-(4-biphenyl)-1,2,4-triazole (p-EtTAZ), bathophenanthroline (BPhen), 2,9-dimethyl-4,7-diphenyl Any one or more of 1,10-phenanthroline (BCP), and 4,4′-bis(5-methylbenzoxazol-2-yl)stilbene (BzOs). In addition, the material of the electron transport layer may further include 8-hydroxyquinoline-lithium (Liq) or the like.

In an exemplary embodiment, a thickness of the hole block layer may be about 5 nm to 15 nm, and a thickness of the electron transport layer may be about 20 nm to 50 nm.

In an exemplary embodiment, an electron injection layer may be made of an alkali metal or a metal, such as lithium fluoride (LiF), ytterbium (Yb), magnesium (Mg), or Calcium (Ca), or a compound of these alkali metals or metals. In an exemplary embodiment, a thickness of the electron injection layer may be about 0.5 nm to 2 nm.

In an exemplary embodiment, the cathode may be made of any one or more of magnesium (Mg), silver (Ag), aluminum (Al), copper (Cu), and lithium (Li), or an alloy made of any one or more of the above metals.

In an exemplary embodiment, the light emitting device may be a red light device, such as a red OLED device.

An embodiment of the present disclosure further provides a display apparatus, which may include the light emitting device as described above.

The display apparatus may be any product or component with a display function, such as a mobile phone, a tablet computer, a television, a display, a laptop computer, a digital photo frame, a navigator, a vehicle-mounted display, a smart watch, and a smart bracelet.

The advantages of the light emitting device according to some exemplary embodiments of the present disclosure in reducing efficiency roll off are described below taking a red light device as an example.

Physical properties of the materials involved are shown in Table 1.

TABLE 1

| | | | | | μh | μe |
|---|---|---|---|---|---|---|
| | HOMO | LUMO | T1. | Tg | (hole mobility) | (electron mobility) |
| | eV | eV | eV | ° C. | cm²/v · s | cm²/v · s |
| P1 | 5.26 | 2.25 | 2.62 | 110 | 6.8 × 10⁻⁶ | — |
| P3 | 5.24 | 2.26 | 2.59 | 108 | 5.4 × 10⁻⁵ | — |
| P5 | 5.29 | 2.28. | 2.61 | 112 | 6.1 × 10⁻⁵ | — |
| P7 | 5.44 | 2.32 | 2.70 | 100 | 1.6 × 10⁻⁶ | — |
| N1 | 5.86 | 2.84 | 2.59 | 123 | — | 6.6 × 10⁻⁶ |
| N2 | 5.84 | 2.81 | 2.61 | 118 | — | 1.9 × 10⁻⁵ |
| N3 | 5.88 | 2.88 | 2.56 | 114 | — | 7.4 × 10⁻⁶ |
| N4 | 5.72 | 2.69 | 2.68 | 108 | — | 1.6 × 10⁻⁶ |
| RD | 5.01 | 3.02 | 2.12 | — | — | — |
| Embodiment | — | — | 2.41. | — | — | — |
| 1 RH | | | | | | |
| Embodiment | — | — | 2.38. | — | — | — |
| 2 RH | | | | | | |
| Embodiment | — | — | 2.36. | — | — | — |
| 3 RH | | | | | | |
| Embodiment | | | 2.41. | | | |
| 4 RH | | | | | | |
| Embodiment | | | 2.41. | | | |
| 5 RH | | | | | | |
| Comparative | — | — | 2.54. | — | — | — |
| Example 1 | | | | | | |
| RH | | | | | | |

### Embodiment 1

A glass plate with ITO (Indium Tin Oxide) is ultrasonically treated in a cleaning agent, then rinsed with deionized water, degreased ultrasonically in acetone-ethanol mixed solvent, and dried in a clean environment at 100° C. until water is completely removed; and the cleaned and dried ITO glass is placed in a vacuum evaporation device, and evaporated to form a hole injection layer, a hole transport layer, an auxiliary light emitting layer, an emitting layer, a hole barrier layer, an electron transport layer, an electron injection layer and a cathode in sequence.

The hole injection layer is made of TAPC: HAT-CN (4% mass ratio doped into TAPC), and its evaporation thickness is 10 nm. The hole transport layer is made of TAPC, and its evaporation thickness is 100 nm. The auxiliary light emitting layer is made of NPB, and its evaporation thickness is 80 nm. The emitting layer is made of P1:N1 (4:6): Ir (piq)₃ (2% mass ratio doped into P1:N1), and its evaporation thickness is 40 nm. The hole barrier layer is made of BCP, and its evaporation thickness is 5 nm. The electron transport layer is made of TAZ: Liq (1:1), and its evaporation thickness is 30 nm. The electron injection layer is made of Liq, and its evaporation thickness is 1 nm.

The P-type host material of the emitting layer is P1, and the N-type host material is N1.

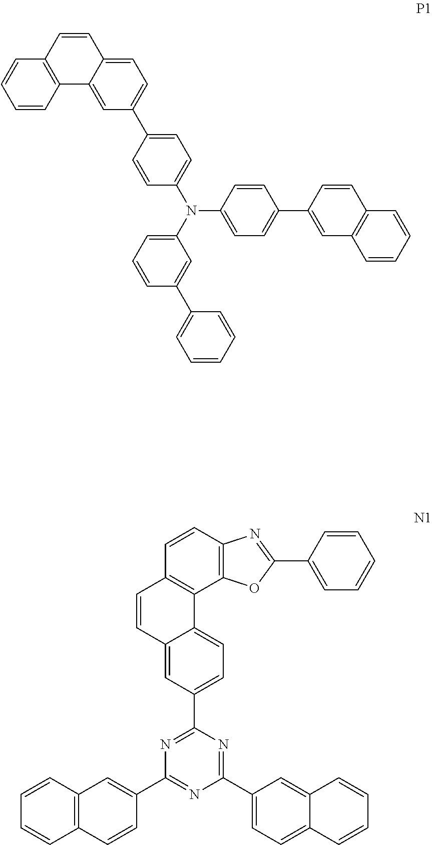 [SMILES: c1ccc(-c2cccc(N(c3ccc(-c4ccc5ccccc5c4)cc3)c3ccc(-c4ccc5ccc6ccccc6c5c4)cc3)c2)cc1 ; c1ccc(-c2nc3ccc4ccc5cc(-c6nc(-c7ccc8ccccc8c7)nc(-c7ccc8ccccc8c7)n6)ccc5c4c3o2)cc1]

### Embodiment 2

The P-type host material of the emitting layer is P3, the N-type host material is N2, and the others are the same as those in Embodiment 1.

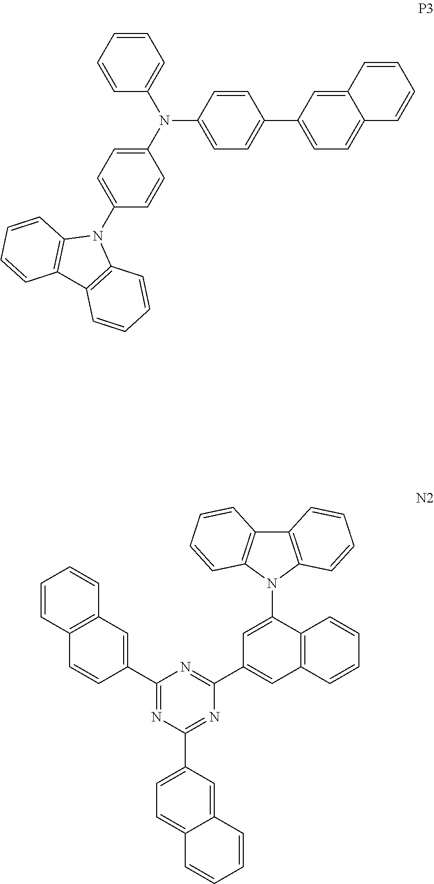 [SMILES: c1ccc(N(c2ccc(-c3ccc4ccccc4c3)cc2)c2ccc(-n3c4ccccc4c4ccccc43)cc2)cc1 ; c1ccc2cc(-c3nc(-c4ccc5ccccc5c4)nc(-c4cc(-n5c6ccccc6c6ccccc65)c5ccccc5c4)n3)ccc2c1]

### Embodiment 3

The P-type host material of the emitting layer is P5, the N-type host material is N3, and the others are the same as those in Embodiment 1.

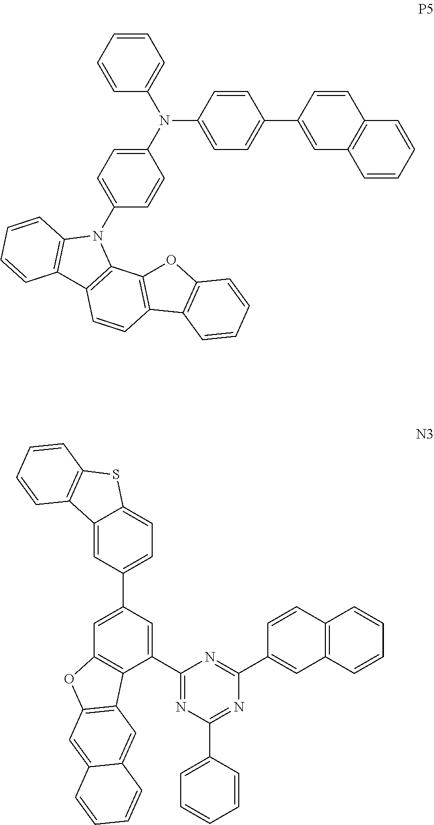 [SMILES: c1ccc(N(c2ccc(-c3ccc4ccccc4c3)cc2)c2ccc(-n3c4ccccc4c4ccc5c6ccccc6oc5c43)cc2)cc1 ; c1ccc(-c2nc(-c3ccc4ccccc4c3)nc(-c3cc(-c4ccc5sc6ccccc6c5c4)cc4oc5cc6ccccc6cc5c34)n2)cc1]

### Embodiment 4

The P-type host material of the emitting layer is P1, the N-type host material is N1, the molar ratio of the P-type host material to the N-type host material is 5:5, and the others are the same as those in Embodiment 1.

### Embodiment 5

The P-type host material of the emitting layer is P1, the N-type host material is N1, the molar ratio of the P-type host material to the N-type host material is 6:4, and the others are the same as those in Embodiment 1.

### Comparative Example 1

The P-type host material of the emitting layer is P7, the N-type host material is N4, and the others are the same as those in Embodiment 1.

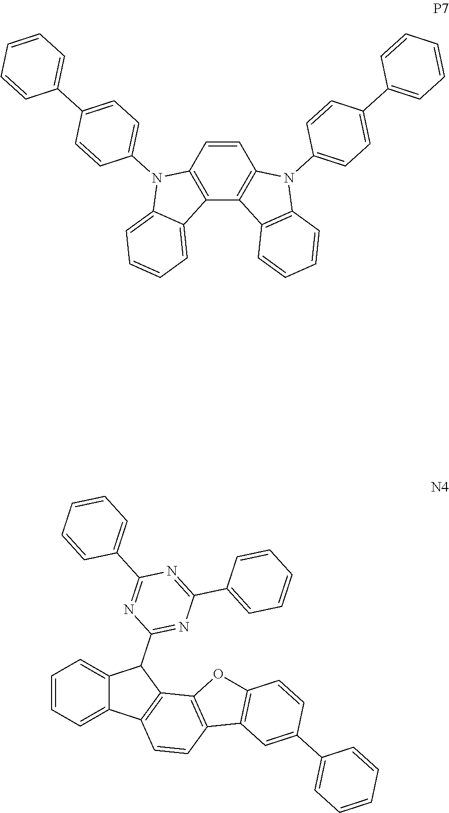 [SMILES: c1ccc(-c2ccc(-n3c4ccccc4c4c5c6ccccc6n(-c6ccc(-c7ccccc7)cc6)c5ccc43)cc2)cc1 ; c1ccc(-c2ccc3oc4c5c(ccc4c3c2)-c2ccccc2C5c2nc(-c3ccccc3)nc(-c3ccccc3)n2)cc1]

FIG. 4 is a photoluminescence spectrum of a host material (RH-PL) and an MLCT3 absorption spectrum of a guest material (RD-MLCT3) of an emitting layer of a device according to an exemplary embodiment and a comparative example of the present disclosure. As may be seen from FIG. 4 and Table 2, an overlapping integral area of the photoluminescence spectrum of the host material and the MLCT3 absorption spectrum of the guest material of the emitting layer of the device according to the exemplary embodiment of the present disclosure is not less than 20% of the photoluminescence spectral integral area of the host material.

The performance of the devices of the above embodiment and comparative example is tested using an IVL, (Current-Voltage-Luminance and Lifetime) device, wherein voltage (V), efficiency and color coordinates (CIE x, CIE y) are measured at room temperature and 15 mA/cm². Efficiency roll off is compared with 0.01 mA/cm² and 15 mA/cm² efficiency drop percentages. The life of the device is measured at 25° C. and 0.6 mA.

The measurement results are shown in Table 2.

TABLE 2

| | | | | | | | Proportion of |
|---|---|---|---|---|---|---|---|
| | Voltage | | | | Life Time | Efficiency | overlapping |
| | (V) | Cd/A | CIE x | CIE y | LT95 (h) | roll off | integral area |
| Embodiment | 91% | 114% | 0.68 | 0.31 | 126% | 5.2% | 50% |
| 1 | | | | | | | |
| Embodiment | 93% | 112% | 0.68 | 0.31 | 122% | 4.8% | 35% |
| 2 | | | | | | | |
| Embodiment | 89% | 115% | 0.68 | 0.31 | 123% | 5.4% | 20% |
| 3 | | | | | | | |
| Embodiment | 90% | 110% | 0.68 | 0.31 | 128% | 5.1% | 60% |
| 4 | | | | | | | |
| Embodiment | 88% | 108% | 0.68 | 0.31 | 131% | 5.3% | 55% |
| 5 | | | | | | | |
| Comparative | 100% | 100% | 0.68 | 0.31 | 100% | 9.8% | 5% |
| Example 1 | | | | | | | |

Note: The performance of the device is based on the data of Comparative Example 1, and its voltage, efficiency and life data are set to 100%; the proportion of overlapping integral area represents the proportion of the overlapping integral area of the photoluminescence spectrum of the host material and the MLCT3 absorption spectrum of the guest material of the emitting layer in the photoluminescence spectral integral area of the host material of the emitting layer.

As can be seen, the lifetime and efficiency roll-off of the device of the exemplary embodiment of the present disclosure are significantly lower than those of the device of the Comparative Example.

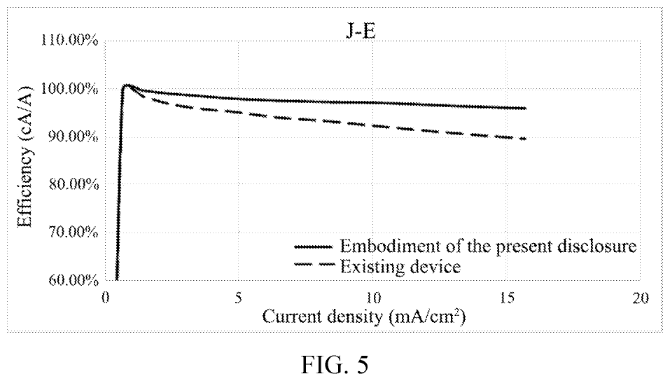

FIG. 5 is curves showing variation of efficiency of a light emitting device according to an exemplary embodiment of the present disclosure and variation of efficiency of a current light emitting device with a current density. As can be seen, the efficiency roll-off of the light emitting device of the exemplary embodiment of the present disclosure is significantly lower at a large current density.

The advantages of the light emitting device according to some exemplary embodiments of the present disclosure in reducing turn-on voltage of the device are described below taking a red light device as an example.

Physical properties of the materials involved are shown in Table 3.

TABLE 3

| | HOMO | LUMO | T1 | μh (hole mobility) |
|---|---|---|---|---|
| | eV | eV | eV | cm²/v · s |
| F1 | 5.45 | 2.36 | 2.65 | 6.8 × 10⁻⁶ |
| F2 | 5.48 | 2.37 | 2.67 | 5.4 × 10⁻⁶ |
| F3 | 5.50 | 2.38 | 2.66 | 6.1 × 10⁻⁶ |
| F4 | 5.28 | 2.31 | 2.58 | 5.5 × 10⁻⁵ |
| P2 | 5.30 | 2.23 | 2.63 | 6.4 × 10⁻⁵ |
| P4 | 5.33 | 2.28 | 2.61 | 5.6 × 10⁻⁵ |
| P6 | 5.32 | 2.30 | 2.64 | 4.7 × 10⁻⁵ |
| P7 | 5.44 | 2.46 | 2.66 | 4.2 × 10⁻⁵ |

### Embodiment 6

A glass plate with ITO is ultrasonically treated in a cleaning agent, then rinsed with deionized water, degreased ultrasonically in acetone-ethanol mixed solvent, and dried in a clean environment at 100° C. until water is completely removed; and
the cleaned and dried ITO glass is placed in a vacuum evaporation device, and evaporated to form a hole injection layer, a hole transport layer, an auxiliary light emitting layer, an emitting layer, a hole barrier layer, an electron transport layer, an electron injection layer and a cathode in sequence.

The hole injection layer is made of TAPC: HAT-CN (4% mass ratio doped into TAPC), and its evaporation thickness is 10 nm. The hole transport layer is made of TAPC, and its evaporation thickness is 100 nm. The auxiliary light emitting layer is made of F1, and its evaporation thickness is 80 nm. The emitting layer is made of P2:N1 (4:6): Ir (piq)₃ (2% mass ratio doped into P2:N1), and its evaporation thickness is 40 nm. The hole barrier layer is made of BCP, and its evaporation thickness is 5 nm. The electron transport layer is made of TAZ: Liq (1:1), and its evaporation thickness is 30 nm. The electron injection layer is made of Liq, and its evaporation thickness is 1 nm.

The material RF of the auxiliary light emitting layer is F1, and the P-type host material is P2.

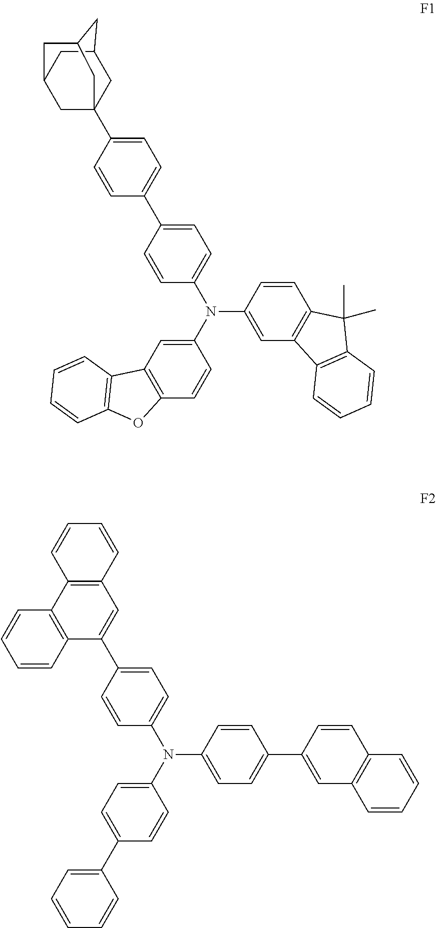 [SMILES: CC1(C)c2ccccc2-c2cc(N(c3ccc(-c4ccc(C56CC7CC(CC(C7)C5)C6)cc4)cc3)c3ccc4oc5ccccc5c4c3)ccc21 ; c1ccc(-c2ccc(N(c3ccc(-c4ccc5ccccc5c4)cc3)c3ccc(-c4cc5ccccc5c5ccccc45)cc3)cc2)cc1]

### Embodiment 7

The material RF of the auxiliary light emitting layer is F2, the P-type host material is P4, and the others are the same as those in Embodiment 6.

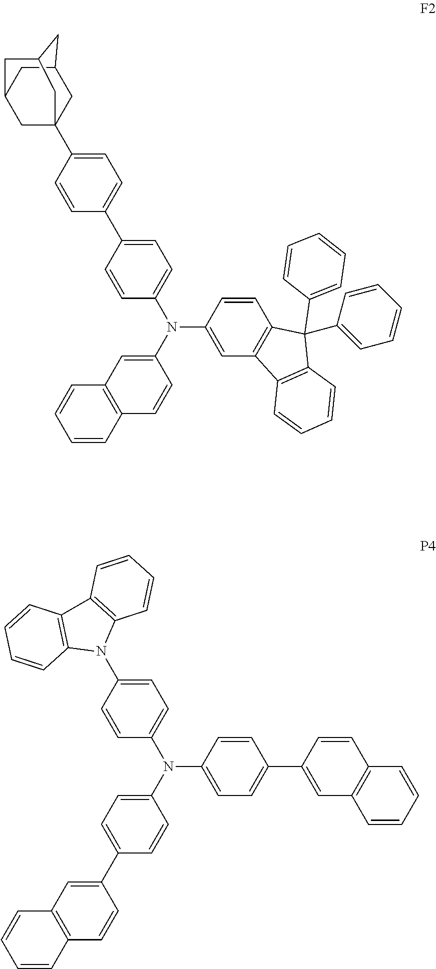 [SMILES: c1ccc(C2(c3ccccc3)c3ccccc3-c3cc(N(c4ccc(-c5ccc(C67CC8CC(CC(C8)C6)C7)cc5)cc4)c4ccc5ccccc5c4)ccc32)cc1 ; c1ccc2cc(-c3ccc(N(c4ccc(-c5ccc6ccccc6c5)cc4)c4ccc(-n5c6ccccc6c6ccccc65)cc4)cc3)ccc2c1]

### Embodiment 8

The material RF of the auxiliary light emitting layer is F3, the P-type host material is P6, and the others are the same as those in Embodiment 6.

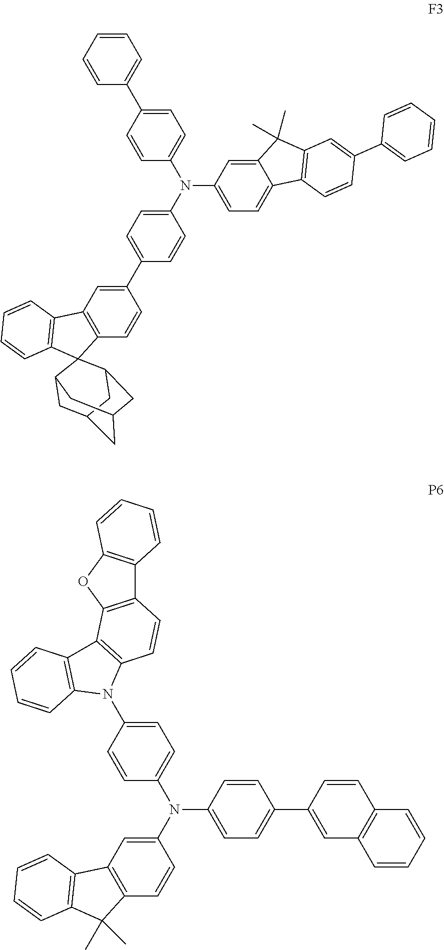 [SMILES: CC1(C)c2cc(-c3ccccc3)ccc2-c2ccc(N(c3ccc(-c4ccccc4)cc3)c3ccc(-c4ccc5c(c4)-c4ccccc4C54C5CC6CC(C5)CC4C6)cc3)cc21 ; CC1(C)c2ccccc2-c2cc(N(c3ccc(-c4ccc5ccccc5c4)cc3)c3ccc(-n4c5ccccc5c5c6oc7ccccc7c6ccc54)cc3)ccc21]

### Comparative Example 2

The material RF of the auxiliary light emitting layer is F4, the P-type host material is P7, and the others are the same as those in Embodiment 6.

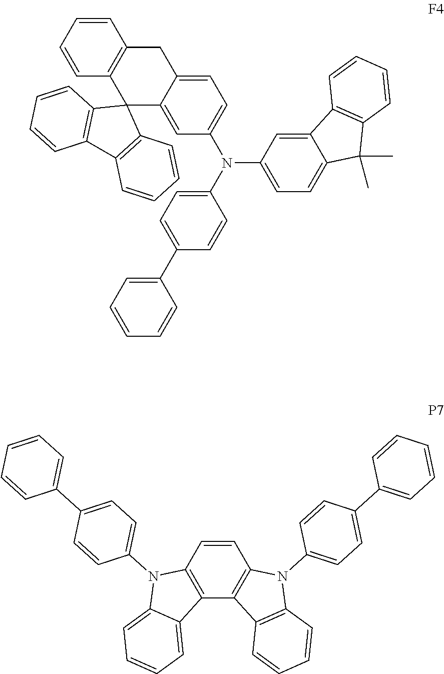 [SMILES: CC1(C)c2ccccc2-c2cc(N(c3ccc(-c4ccccc4)cc3)c3ccc4c(c3)C3(c5ccccc5C4)c4ccccc4-c4ccccc43)ccc21 ; c1ccc(-c2ccc(-n3c4ccccc4c4c5c6ccccc6n(-c6ccc(-c7ccccc7)cc6)c5ccc43)cc2)cc1]

The performance of the devices of the above embodiment and comparative example is tested using an IVL (Current-Voltage-Luminance and Lifetime) device, wherein voltage (V), efficiency and color coordinates (CIE x, CIE y) are measured at room temperature and 15 mA/cm². The life of the device is measured at 25° C. and 0.6 mA.

The measurement results are shown in Table 4.

TABLE 4

| | Voltage | | | | Life time | Turn-on voltage |
|---|---|---|---|---|---|---|
| | (V) | Cd/A | CIE x | CIE y | LT95 (h) | Von (V) |
| Embodiment | 91% | 114% | 0.68 | 0.31 | 126% | 108% |
| 6 | | | | | | |
| Embodiment | 93% | 112% | 0.68 | 0.31 | 122% | 112% |
| 7 | | | | | | |
| Embodiment | 89% | 115% | 0.68 | 0.31 | 123% | 111% |
| 8 | | | | | | |
| Comparative | 100% | 100% | 0.68 | 0.31 | 100% | 100% |
| Example 2 | | | | | | |

Note: The performance of the device is based on the data of Comparative Example 2, and the voltage, turn-on voltage and life data are set to 100%.

As can be seen, the material of the auxiliary light emitting layer and the P-type host material in the light emitting material selected for the device of the exemplary embodiment of the present disclosure may improve the turn-on voltage of the device to a certain extent, thereby better matching with the turn-on voltage of the blue light device and the green light device and improving the crosstalk phenomenon.

Although the embodiments disclosed in the present disclosure are as above, the described contents are only embodiments used for convenience of understanding the present disclosure and are not intended to limit the present disclosure. Any person skilled in the art of the present disclosure may make any modification and change in forms and details of implementation without departing from the spirit and scope disclosed in the present disclosure. However, the scope of patent protection of the present disclosure is still subject to the scope defined in the appended claims.

1. A light emitting material for an organic light emitting device, comprising a host material, wherein the host material comprises a first compound having the following structural general formula: 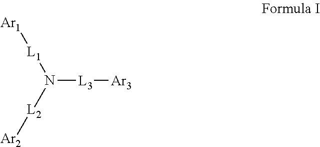
where L₁ to L₃ each independently comprise any one of a single bond, phenylene, biphenylene, naphthylene, fluorenylene, dimethylfluorenyl, and C1-C10 alkylene;
Ar₁ to Ar₃ each independently comprise any one of substituted or unsubstituted phenyl, substituted or unsubstituted biphenyl, substituted or unsubstituted naphthyl, substituted or unsubstituted anthryl, substituted or unsubstituted phenanthrenyl, substituted or unsubstituted carbazole, substituted or unsubstituted dibenzofuryl, substituted or unsubstituted dibenzothienyl, substituted or unsubstituted 9-hydrofluorenyl, substituted or unsubstituted 9,9-dimethylfluorenyl, substituted or unsubstituted 9,9-diphenylfluorenyl, substituted or unsubstituted spirofluorenyl, a substituted or unsubstituted group represented by Formula II, and a substituted or unsubstituted group represented by Formula III, wherein substituted phenyl, substituted biphenyl, substituted naphthyl, substituted anthryl, substituted phenanthrenyl, substituted carbazole, substituted dibenzofuryl, substituted dibenzothienyl, substituted 9-hydrofluorenyl, substituted 9,9-dimethylfluorenyl, substituted 9,9-diphenylfluorenyl, substituted spirofluorenyl, substituted group represented by Formula II, and substituted group represented by Formula III mean being substituted by one or more of the following groups: phenyl, biphenyl, naphthyl, anthryl, phenanthrenyl, carbazolyl, dibenzofuryl, dibenzothienyl, 9-hydrofluorenyl, 9,9-dimethylfluorenyl, 9, 9-diphenylfluorenyl, spirofluorenyl, C1 to C10 alkyl, a group represented by Formula II, and a group represented by Formula III; 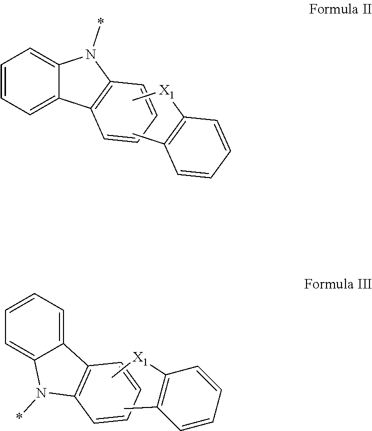
where X₁ comprises any one of O, S, NR₁ and CR₂R₃; and
R₁ to R₃ each independently comprise any one of hydrogen, C1 to C10 alkyl, phenyl, biphenyl, naphthyl, anthryl, phenanthrenyl, carbazole, dibenzofuryl, dibenzothienyl, fluorenyl, dimethylfluorenyl, diphenylfluorenyl, spirofluorenyl.

2. The light emitting material for the organic light emitting device according to claim 1, wherein L1 to L3 each independently comprise any one of a single bond, and phenylene; and
Ar₁ to Ar₃ each independently comprise any one of phenyl, benzene-substituted phenyl, biphenyl-substituted phenyl, phenanthrene-substituted phenyl, carbazole-substituted phenyl, biphenyl, phenanthrene, carbazole, dimethylfluorenyl, a group represented by Formula II, and a group represented by Formula III, wherein in the group represented by Formula II and the group represented by Formula III, X₁ is O.

3. The light emitting material for the organic light emitting device according to claim 1, wherein the first compound comprises any one of:

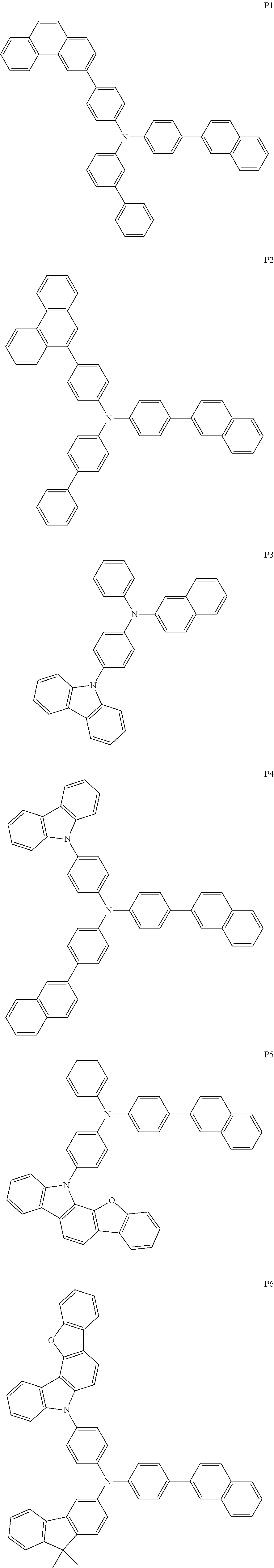 [SMILES: c1ccc(-c2cccc(N(c3ccc(-c4ccc5ccccc5c4)cc3)c3ccc(-c4ccc5ccc6ccccc6c5c4)cc3)c2)cc1 ; c1ccc(-c2ccc(N(c3ccc(-c4ccc5ccccc5c4)cc3)c3ccc(-c4cc5ccccc5c5ccccc45)cc3)cc2)cc1 ; c1ccc(N(c2ccc(-n3c4ccccc4c4ccccc43)cc2)c2ccc3ccccc3c2)cc1 ; c1ccc2cc(-c3ccc(N(c4ccc(-c5ccc6ccccc6c5)cc4)c4ccc(-n5c6ccccc6c6ccccc65)cc4)cc3)ccc2c1 ; c1ccc(N(c2ccc(-c3ccc4ccccc4c3)cc2)c2ccc(-n3c4ccccc4c4ccc5c6ccccc6oc5c43)cc2)cc1 ; CC1(C)c2ccccc2-c2cc(N(c3ccc(-c4ccc5ccccc5c4)cc3)c3ccc(-n4c5ccccc5c5c6oc7ccccc7c6ccc54)cc3)ccc21]

4. The light emitting material for the organic light emitting device according to claim 1, further comprising a guest material, wherein the host material and the guest material satisfy:
0.1 eV≤T1(H)−T1(D)≤0.5 eV;
2.1 eV≤T1(H)≤2.7 eV; and
2.0 eV≤T1(D)≤2.2 eV;
where T1 (H) is a lowest triplet state energy of the host material, and T1 (D) is a lowest triplet state energy of the guest material.

5. The light emitting material for the organic light emitting device according to claim 4, wherein the host material further comprises a second compound, and the first compound and the second compound satisfy:
2.2 eV≤T1(P)≤2.8 eV; and
2.2 eV≤T1(N)≤2.8 eV;
where T1 (P) is a lowest triplet state energy of the first compound, and T1 (N) is a lowest triplet state energy of the second compound.

6. The light emitting material for the organic light emitting device according to claim 5, wherein the first compound, the second compound and the guest material satisfy:
0.1 eV≤|HOMO(P)−HOMO(D)|≤0.4 eV; and
0.1 eV≤|LUMO(N)−LUMO(D)|≤0.5 eV;
where HOMO (P) is a highest occupied molecular orbital energy level of the first compound; LUMO (N) is a lowest unoccupied molecular orbital energy level of the second compound; HOMO (D) is a highest occupied molecular orbital energy level of the guest material; and LUMO (D) is a lowest unoccupied molecular orbital energy level of the guest material.

7. The light emitting material for the organic light emitting device according to claim 4, wherein an overlapping integral area of a photoluminescence spectrum of the host material and a metal-to-ligand charge transfer absorption spectrum of the guest material is not less than 20% of a spectral integral area of the photoluminescence spectrum of the host material.

8. The light emitting material for the organic light emitting device according to claim 5, wherein the second compound have the following general formula: 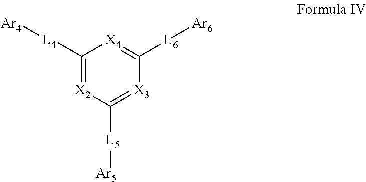
where L₄ to L₆ each independently comprise any one of a single bond, phenylene, biphenylene, naphthylene, fluorenylene, dimethylfluorenyl, and C1-C10 alkylene;
Ar₄ to Ar₆ each independently comprise any one of substituted or unsubstituted phenyl, substituted or unsubstituted biphenyl, substituted or unsubstituted naphthyl, substituted or unsubstituted anthryl, substituted or unsubstituted phenanthrenyl, substituted or unsubstituted carbazole, substituted or unsubstituted dibenzofuryl, substituted or unsubstituted dibenzothienyl, substituted or unsubstituted 9-hydrofluorenyl, substituted or unsubstituted 9,9-dimethylfluorenyl, substituted or unsubstituted 9,9-diphenylfluorenyl, substituted or unsubstituted spirofluorenyl, a substituted or unsubstituted group represented by Formula V, and a substituted or unsubstituted group represented by Formula VI, wherein substituted phenyl, substituted biphenyl, substituted naphthyl, substituted anthryl, substituted phenanthrenyl, substituted carbazole, substituted dibenzofuryl, substituted dibenzothienyl, substituted 9-hydrofluorenyl, substituted 9,9-dimethylfluorenyl, substituted 9,9-diphenylfluorenyl, substituted spirofluorenyl, substituted group represented by Formula V, and substituted group represented by Formula VI mean being substituted by one or more of the following groups: phenyl, biphenyl, naphthyl, anthryl, phenanthrenyl, carbazolyl, dibenzofuryl, dibenzothienyl, 9-hydrofluorenyl, 9,9-dimethylfluorenyl, 9,9-diphenylfluorenyl, spirofluorenyl, C1 to C10 alkyl, a group represented by Formula V, and a group represented by Formula VI; 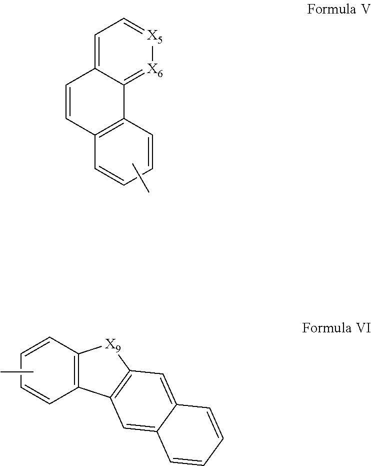
where at least one of X₂ and X₃ is N, and the other is any one of N and —CH; X₄ is N; and
X₅ and X₆ each independently comprise any one of N, C and CH, wherein when both X₅ and X₆ are C, X₅ and X₆ form a ring, which then forms a group represented by Formula V-1 or Formula V-2; 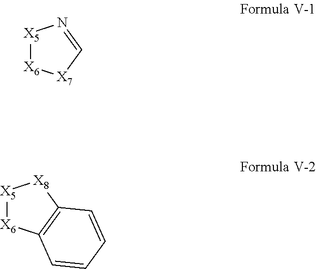
X₇ to X₉ each independently comprise any one of O, S, NR₄ and CR₅R₆; and
R₄ to R₆ each independently comprise any one of hydrogen, C1 to C10 alkyl, phenyl, biphenyl, naphthyl, anthryl, phenanthrenyl, carbazole, dibenzofuryl, dibenzothienyl, fluorenyl, dimethylfluorenyl, diphenylfluorenyl, spirofluorenyl.

9. The light emitting material for the organic light emitting device according to claim 8, wherein L₄ to L₆ each independently comprise any one of a single bond, and naphthylene; and
Ar₄ to Ar₆ each independently comprise any one of phenyl, naphthyl, carbazolyl, carbazole substituted naphthyl,

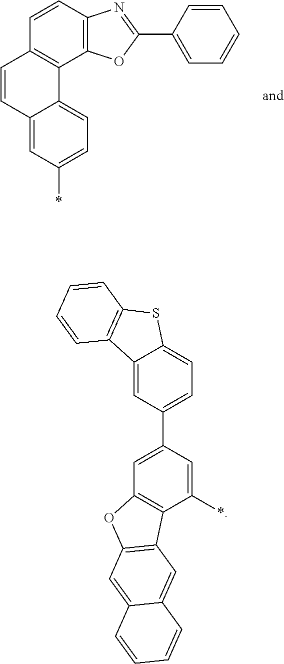

10. The light emitting material for the organic light emitting device according to claim 8, wherein the second compound comprises any one of the following compounds:

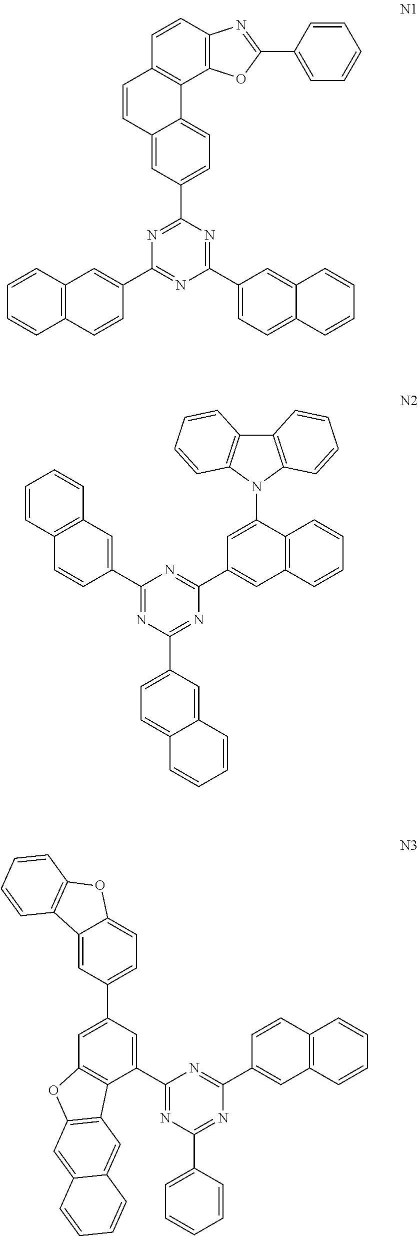 [SMILES: c1ccc(-c2nc3ccc4ccc5cc(-c6nc(-c7ccc8ccccc8c7)nc(-c7ccc8ccccc8c7)n6)ccc5c4c3o2)cc1 ; c1ccc2cc(-c3nc(-c4ccc5ccccc5c4)nc(-c4cc(-n5c6ccccc6c6ccccc65)c5ccccc5c4)n3)ccc2c1 ; c1ccc(-c2nc(-c3ccc4ccccc4c3)nc(-c3cc(-c4ccc5oc6ccccc6c5c4)cc4oc5cc6ccccc6cc5c34)n2)cc1]

11. The light emitting material for the organic light emitting device according to claim 5, wherein
the first compound is P1, and the second compound is N1; or,
the first compound is P3, and the second compound is N2; or,
the first compound is P5, and the second compound is N3.

12. The light emitting material for the organic light emitting device according to claim 5, wherein the first compound and the second compound satisfy:
80° C.≤Tg(P)≤140° C.;
80° C.≤Tg(N)≤140° C.; and

|Tg(P)−Tg(N)|≤20° C.;
where Tg (P) is a glass transition temperature of the first compound, and Tg (N) is a glass transition temperature of the second compound.

13. The light emitting material for the organic light emitting device according to claim 5, wherein in the host material, a molar ratio of the first compound to the second compound is 3:7 to 7:3.

14. A light emitting device, comprising a light emitting layer, wherein a material of the light emitting layer comprise the light emitting material for the organic light emitting device according to claim 1.

15. The light emitting device according to claim 14, further comprising an auxiliary light emitting layer provided on one side of the light emitting layer, and a material of the auxiliary light emitting layer and the first compound satisfy:
1/100≤hole mobility(F)/hole mobility(P)≤1;
where hole mobility (F) is a hole mobility of the material of the auxiliary light emitting layer, and hole mobility (P) is a hole mobility of the first compound.

16. The light emitting device according to claim 15, wherein the material of the auxiliary light emitting layer and the first compound further satisfy:
0.1 eV≤|HOMO(F)−HOMO(P)|≤0.5 eV; and

|HOMO(F)|>|HOMO(P)|;
where HOMO (F) is a highest occupied molecular orbital (HOMO) energy level of the material of the auxiliary light emitting layer,
wherein the material of the auxiliary light emitting layer and the first compound further satisfy:
0 eV≤T1(F)−T1(P)≤0.4 eV:
where T1 (F) is a lowest triplet state energy of the material of the auxiliary light emitting layer.

17. (canceled)

18. The light emitting device according to claim 15, wherein the material of the auxiliary light emitting layer has the following general formula: 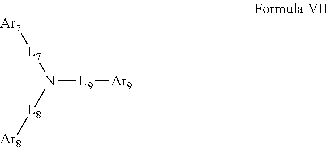
where L₇ to L₉ each independently comprise any one of a single bond, phenylene, biphenylene, naphthylene, fluorenylene, dimethylfluorenyl, and C1-C10 alkylene;
Ar₇ to Ar₉ each independently comprise substituted or unsubstituted phenyl, substituted or unsubstituted biphenyl, substituted or unsubstituted naphthyl, substituted or unsubstituted dibenzofuryl, substituted or unsubstituted dibenzothienyl, substituted or unsubstituted 9-hydrofluorenyl, substituted or unsubstituted 9,9-dimethylfluorenyl, substituted or unsubstituted 9,9-diphenylfluorenyl, substituted or unsubstituted spirofluorenyl, substituted or unsubstituted adamantyl, and a substituted or unsubstituted group represented by Formula VIII, wherein substituted phenyl, substituted biphenyl, substituted naphthyl, substituted dibenzofuryl, substituted dibenzothienyl, substituted 9-hydrofluorenyl, substituted 9,9-dimethylfluorenyl, substituted 9,9-diphenylfluorenyl, substituted spirofluorenyl, substituted adamantyl, and substituted group represented by Formula VIII mean being substituted by one or more of the following groups: phenyl, biphenyl, naphthyl, dibenzofuryl, dibenzothienyl, 9-hydrofluorenyl, 9,9-dimethylfluorenyl, 9,9-diphenylfluorenyl, spirofluorenyl, C1 to C10 alkyl, adamantyl, and a group represented by Formula VIII; and 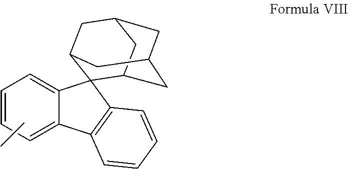
R₇ to R₉ each independently comprise any one of hydrogen, C1 to C10 alkyl, phenyl, biphenyl, naphthyl, anthryl, phenanthrenyl, carbazole, dibenzofuryl, dibenzothienyl, fluorenyl, dimethylfluorenyl, diphenylfluorenyl, spirofluorenyl,
wherein L₇ to L₉ each independently comprise any one of a single bond, phenylene, biphenylene, and dimethylfluorenyl; and
Ar₇ to Ar₉ each independently comprise any one of adamantane-substituted phenyl, adamantane-substituted biphenyl, adamantyl, dibenzofuryl, dimethylfluorenyl, spirofluorenyl, benzene-substituted dimethylfluorenyl, and a group represented by Formula VIII.

19. (canceled)

20. The light emitting device according to claim 18, wherein the material of the auxiliary light emitting layer comprises any one of the following compounds:

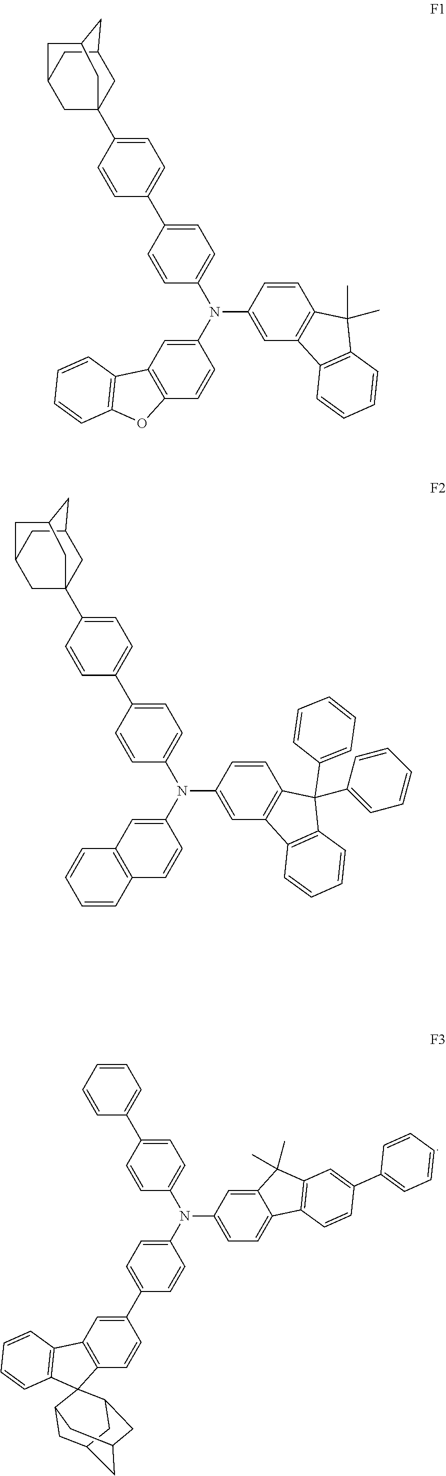 [SMILES: CC1(C)c2ccccc2-c2cc(N(c3ccc(-c4ccc(C56CC7CC(CC(C7)C5)C6)cc4)cc3)c3ccc4oc5ccccc5c4c3)ccc21 ; c1ccc(C2(c3ccccc3)c3ccccc3-c3cc(N(c4ccc(-c5ccc(C67CC8CC(CC(C8)C6)C7)cc5)cc4)c4ccc5ccccc5c4)ccc32)cc1 ; CC1(C)c2cc(-c3ccccc3)ccc2-c2ccc(N(c3ccc(-c4ccccc4)cc3)c3ccc(-c4ccc5c(c4)-c4ccccc4C54C5CC6CC(C5)CC4C6)cc3)cc21]

21. The light emitting device according to claim 20, wherein
the first compound is P2, and the material of the auxiliary light emitting layer is F1; or
the first compound is P4, and the material of the auxiliary light emitting layer is F2; or
the first compound is P6, and the material of the auxiliary light emitting layer is F3.

22. A display apparatus, comprising the light emitting device according to claim 14.
